(19) United States
(12) Patent Application Publication
(10) Pub. No.: US 2026/0079399 A1
(43) Pub. Date: Mar. 19, 2026

(54) POLYMERS, PHOTORESIST COMPOSITIONS AND METHODS OF FORMING PATTERNS

(71) Applicant: DuPont Electronic Materials International, LLC, Marlborough, MA (US)

(72) Inventors: Li Cui, Westborough, MA (US); Emad Aqad, Northborough, MA (US); K. A. Niradha Sachinthani, Grafton, MA (US); Jong Keun Park, Shrewsbury, MA (US); Choong-Bong Lee, Westborough, MA (US); Philjae Kang, Osan-si (KR)

(21) Appl. No.: 18/890,150

(22) Filed: Sep. 19, 2024

(51) Int. Cl. G03F 7/039; G03F 7/004; G03F 7/38

(52) U.S. Cl. CPC G03F 7/0397; G03F 7/0045; G03F 7/0048; G03F 7/38

(57) ABSTRACT

A polymer comprising a first repeating unit derived from a polymerizable compound comprising an aromatic group, wherein the aromatic group is substituted with: a first substituent group comprising an ethylenically unsaturated double bond; a second substituent group that is a hydroxyl group; and a third substituent group comprising a carbonyl group, wherein the first substituent group, the second substituent group, and the carbonyl group of the third substituent group are each bonded to a different carbon atom of the aromatic group; and a second repeating unit comprising a base-labile group, wherein the first repeating unit and the second repeating unit are structurally different.

### FIELD

The present invention relates to polymers that include a base-switchable functional group and photoresist compositions including the same. The invention finds particular applicability in lithographic applications in the semiconductor manufacturing industry.

### BACKGROUND

Photoresist compositions are photosensitive materials used to transfer a pattern to one or more underlying layers, such as a metal, semiconductor, or dielectric layer disposed on a substrate. Positive-tone chemically amplified photoresist compositions are conventionally used for high-resolution processing. Such resist compositions typically include a polymer having acid-labile groups and a photoacid generator (PAG). A layer of the photoresist composition is pattern-wise exposed to activating radiation and the PAG generates an acid in the exposed regions. During post-exposure baking, the acid causes cleavage of the polymer's acid-labile groups. This creates a difference in solubility characteristics between exposed and unexposed regions of the photoresist layer in a developer solution. In a positive tone development (PTD) process, exposed regions of the photoresist layer become soluble in a developer, typically an aqueous base developer, and are removed from the substrate surface. Unexposed regions, which are insoluble in the developer, remain after development to form a positive relief image. The resulting relief image permits selective processing of the substrate.

To increase the integration density of semiconductor devices and allow for the formation of structures having dimensions in the nanometer (nm) range, photoresists and photolithography processing tools having high-resolution capabilities have been and continue to be developed. One approach to achieving nm-scale feature sizes in semiconductor devices is the use of activating radiation having a short wavelength, for example, 193 nm or less, for exposure of the photoresist layer. To further improve lithographic performance, immersion lithography tools have been developed to effectively increase the numerical aperture (NA) of the lens of the imaging device. This is accomplished by use of a relatively high refractive index fluid, typically water, between the last surface of the imaging device and the upper surface of the semiconductor wafer.

Deep-ultraviolet argon fluoride (ArF) excimer-laser immersion tools are currently pushing the boundaries of lithographic processing to the 16 nm and 14 nm device nodes with the use of multiple (double, triple, or higher order) patterning techniques. The use of multiple patterning, however, can be costly in terms of increased material usage and number of process steps required as compared with single step, directly-imaged patterns. The need for photoresist compositions for next-generation (e.g., Extreme Ultraviolet, EUV) lithography, which uses activating radiation having an extremely short wavelength of 13.5 nm, has thus become of increased importance for advanced device nodes.

At the extreme feature sizes associated with advanced device nodes, the performance requirements of photoresist compositions have become increasingly more stringent. Desired performance properties include, for example, high sensitivity to activating radiation, low unexposed film thickness loss (UFTL), good contrast, high-resolving capability, and good line-width roughness (LWR). It has been found, for example, that stochastic variation in conventional chemically amplified photoresist materials for extreme ultraviolet lithography can lead to patterns having high pattern roughness, resulting in poor pattern fidelity of post-etched features, and negatively impacting device performance characteristics.

Accordingly, there remains a continued need for polymers and photoresists containing such polymers which address one or more problems associated with the state of the art.

### SUMMARY

An aspect provides a polymer comprising a first repeating unit derived from a polymerizable compound comprising an aromatic group, wherein the aromatic group is substituted with: a first substituent group comprising an ethylenically unsaturated double bond; a second substituent group that is a hydroxyl group; and a third substituent group comprising a carbonyl group, wherein the first substituent group, the second substituent group, and the carbonyl group of the third substituent group are each bonded to a different carbon atom of the aromatic group; and a second repeating unit comprising a base-labile group, wherein the first repeating unit and the second repeating unit are structurally different.

Another aspect provides a photoresist composition, comprising the polymer; a photoacid generator; and a solvent.

Still another aspect provides a method for forming a pattern, the method comprising: applying a layer of the photoresist composition of claim 8 or 9 on a substrate to provide a photoresist composition layer; pattern-wise exposing the photoresist composition layer to activating radiation to provide an exposed photoresist composition layer; and developing the exposed photoresist composition layer to provide a photoresist pattern.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the FIGURES, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. The modifier “about” used in connection with a quantity is inclusive of the stated value and has the meaning dictated by the context (e.g., includes the degree of error associated with measurement of the particular quantity). All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another.

When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “actinic rays” or “radiation” means, for example, a bright line spectrum of a mercury lamp, far ultraviolet rays represented by an excimer laser, extreme ultraviolet rays (EUV light), X-rays, particle rays such as electron beams and ion beams, or the like. In addition, in the present invention, “light” means actinic rays or radiation. The krypton fluoride laser (KrF laser) is a particular type of excimer laser, which is sometimes referred to as an exciplex laser. “Excimer” is short for “excited dimer,” while “exciplex” is short for “excited complex.” An excimer laser uses a mixture of a noble gas (argon, krypton, or xenon) and a halogen gas (fluorine or chlorine), which under suitable conditions of electrical stimulation and high pressure, emits coherent stimulated radiation (laser light) in the ultraviolet range. Furthermore, “exposure” in the present specification includes, unless otherwise specified, not only exposure by a mercury lamp, far ultraviolet rays represented by an excimer laser, X-rays, extreme ultraviolet rays (EUV light), or the like, but also writing by particle rays such as electron beams and ion beams.

As used herein, the term “hydrocarbon” refers to an organic compound or group having at least one carbon atom and at least one hydrogen atom; “alkyl” refers to a straight or branched chain saturated hydrocarbon group having the specified number of carbon atoms and having a valence of one; “alkylene” refers to an alkyl group having a valence of two; “hydroxyalkyl” refers to an alkyl group substituted with at least one hydroxyl group (—OH); “alkoxy” refers to “alkyl-O—”; “carboxyl” and “carboxylic acid group” refer to a group having the formula “—C(═O)—OH”; “cycloalkyl” refers to a monovalent group having one or more saturated rings in which all ring members are carbon; “cycloalkylene” refers to a cycloalkyl group having a valence of two; “alkenyl” refers to a straight or branched chain, monovalent hydrocarbon group having at least one carbon-carbon double bond; “alkenoxy” refers to “alkenyl-O—”; “alkenylene” refers to an alkenyl group having a valence of two; “cycloalkenyl” refers to a non-aromatic cyclic divalent hydrocarbon group having at least three carbon atoms, with at least one carbon-carbon double bond; “alkynyl” refers to a monovalent hydrocarbon group having at least one carbon-carbon triple bond; the term “aromatic group” refers to a monocyclic or polycyclic aromatic ring system that satisfies Huckel's Rule (4n+2π electrons) and includes carbon atoms in the ring; the term “heteroaromatic group” refers to an aromatic group that includes one or more heteroatoms (e.g., 1-4 heteroatoms) selected from N, O, and S instead of a carbon atom in the ring; “aryl” refers to a monovalent monocyclic or polycyclic aromatic ring system where every ring member is carbon, and may include a group with an aromatic ring fused to at least one cycloalkyl or heterocycloalkyl ring; “arylene” refers to an aryl group having a valence of two; “alkylaryl” refers to an aryl group that has been substituted with an alkyl group; “arylalkyl” refers to an alkyl group that has been substituted with an aryl group; “aryloxy” refers to “aryl-O— and “arylthio” refers to “aryl-S—”.

The prefix “hetero” means that the compound or group includes at least one member that is a heteroatom (e.g., 1, 2, 3, or 4 or more heteroatom(s)) instead of a carbon atom, wherein the heteroatom(s) is each independently N, O, S, Si, or P; “heteroatom-containing group” refers to a substituent group that includes at least one heteroatom; “heteroalkyl” refers to an alkyl group having at least one heteroatom instead of carbon.

The term “heterocycloalkyl” refers to a cycloalkyl group having at least one heteroatom that is chosen independently from N, O, or S as a ring member instead of carbon; “heterocycloalkylene” refers to a heterocycloalkyl group having a valence of two. Exemplary 3-membered heterocycloalkyl groups containing 1 heteroatom include aziridinyl, oxiranyl, and thiiranyl. Exemplary 4-membered heterocycloalkyl groups containing 1 heteroatom include azetidinyl, oxetanyl, and thietanyl. Exemplary 5-membered heterocycloalkyl groups containing 1 heteroatom include tetrahydrofuranyl, dihydrofuranyl, tetrahydrothiophenyl, dihydrothiophenyl, pyrrolidinyl, dihydropyrrolyl, and pyrrolyl-2,5-dione. Exemplary 5-membered heterocycloalkyl groups containing 2 heteroatoms include dioxolanyl, oxathiolanyl, and dithiolanyl. Exemplary 5-membered heterocycloalkyl groups containing 3 heteroatoms include triazolinyl, oxadiazolinyl, and thiadiazolinyl. Exemplary 6-membered heterocycloalkyl groups containing 1 heteroatom include piperidinyl, tetrahydropyranyl, dihydropyridinyl, and thianyl. Exemplary 6-membered heterocycloalkyl groups containing 2 heteroatoms include piperazinyl, morpholinyl, dithianyl, and dioxanyl. Exemplary 6-membered heterocycloalkyl groups containing 2 heteroatoms include triazinanyl. Exemplary 7-membered heterocycloalkyl groups containing 1 heteroatom include azepanyl, oxepanyl, and thiepanyl. Exemplary 8-membered heterocycloalkyl groups containing 1 heteroatom include azocanyl, oxecanyl and thiocanyl. Exemplary bicyclic heterocycloalkyl groups include indolinyl, isoindolinyl, dihydrobenzofuranyl, dihydrobenzothienyl, tetrahydrobenzo-thienyl, tetrahydrobenzofuranyl, tetrahydroindolyl, tetrahydroquinolinyl, tetrahydroisoquinolinyl, decahydroquinolinyl, decahydroisoquinolinyl, octahydrochromenyl, octahydroisochromenyl, decahydronaphthyridinyl, decahydro-1,8-naphthyridinyl, octahydropyrrolo[3,2-b]pyrrole, indolinyl, phthalimidyl, naphthalimidyl, chromanyl, chromenyl, 1H-benzo[e][1,4]diazepinyl, 1,4,5,7-tetrahydropyrano[3,4-b]pyrrolyl, 5,6-dihydro-4H-furo[3,2-b]pyrrolyl, 6,7-dihydro-5H-furo[3,2-b]pyranyl, 5,7-dihydro-4H-thieno[2,3-c]pyranyl, 2,3-dihydro-1H-pyrrolo[2,3-b]pyridinyl, 2,3-dihydrofuro[2,3-b]pyridinyl, 4,5,6,7-tetrahydro-1H-pyrrolo[2,3-b]pyridinyl, 4,5,6,7-tetrahydrofuro[3,2-c]pyridinyl, 4,5,6,7-tetrahydrothieno[3,2-b]pyridinyl, and 1,2,3,4-tetrahydro-1,6-naphthyridinyl.

The term “heteroaryl” means 4-8 membered monocyclic, 8-12 membered bicyclic, or 11-14 membered tricyclic aromatic ring systems having 1-4 heteroatoms (if monocyclic), 1-6 heteroatoms (if bicyclic), or 1-9 heteroatoms (if tricyclic) that are each independently selected from N, O, or S (e.g., carbon atoms and 1-3, 1-6, or 1-9 heteroatoms independently selected from N, O, or S, if monocyclic, bicyclic, or tricyclic, respectively). Exemplary 5-membered heteroaryl groups containing 1 heteroatom include pyrrolyl, furanyl, and thiophenyl. Exemplary 5-membered heteroaryl groups containing 2 heteroatoms include imidazolyl, pyrazolyl, oxazolyl, isoxazolyl, thiazolyl, and isothiazolyl. Exemplary 5-membered heteroaryl groups containing 3 heteroatoms include triazolyl, oxadiazolyl, and thiadiazolyl. Exemplary 5-membered heteroaryl groups containing 4 heteroatoms include tetrazolyl. Exemplary 6-membered heteroaryl groups containing 1 heteroatom include pyridinyl. Exemplary 6-membered heteroaryl groups containing 2 heteroatoms include pyridazinyl, pyrimidinyl, and pyrazinyl. Exemplary 6-membered heteroaryl groups containing 3 or 4 heteroatoms include triazinyl and tetrazinyl, respectively. Exemplary 7-membered heteroaryl groups containing 1 heteroatom include azepinyl, oxepinyl, and thiepinyl. Exemplary 5,6-bicyclic heteroaryl groups include indolyl, isoindolyl, indazolyl, benzotriazolyl, benzothiophenyl, isobenzothiophenyl, benzofuranyl, benzoisofuranyl, benzimidazolyl, benzoxazolyl, benzisoxazolyl, benzoxadiazolyl, benzthiazolyl, benzisothiazolyl, benzthiadiazolyl, indolizinyl, and purinyl. Exemplary 6,6-bicyclic heteroaryl groups include naphthyridinyl, pteridinyl, quinolinyl, isoquinolinyl, cinnolinyl, quinoxalinyl, phthalazinyl, and quinazolinyl. Exemplary tricyclic heteroaryl groups include, without limitation, phenanthridinyl, dibenzofuranyl, carbazolyl, acridinyl, phenothiazinyl, phenoxazinyl and phenazinyl.

The term “halogen” means a monovalent substituent that is fluorine (fluoro), chlorine (chloro), bromine (bromo), or iodine (iodo). The prefix “halo” means a group including one or more of a fluoro, chloro, bromo, or iodo substituent instead of a hydrogen atom. A combination of halo groups (e.g., bromo and fluoro), or only fluoro groups may be present. For example, the term “haloalkyl” refers to an alkyl group substituted with one or more halogens. As used herein, “substituted C₁₋₈ haloalkyl” refers to a C₁₋₈ alkyl group substituted with at least one halogen, and is further substituted with one or more other substituent groups that are not halogens. It is to be understood that substitution of a group with a halogen atom is not to be considered a heteroatom-containing group, because a halogen atom does not replace a carbon atom.

The term “fluorinated” means having one or more fluorine atoms incorporated into a group instead of hydrogen. For example, where a C₁₋₁₈ fluoroalkyl group is indicated, the fluoroalkyl group can include one or more fluorine atoms, for example, a single fluorine atom, two fluorine atoms (e.g., as a 1,1-difluoroethyl group), three fluorine atoms (e.g., as a 2,2,2-trifluoroethyl group), or fluorine atoms at each valence of carbon (e.g., as a perfluorinated group such as —CF₃, —C₂F₅, —C₃F₇, or —C₄F₉). A “substituted fluoroalkyl group” shall be understood to mean a fluoroalkyl group that is further substituted by at least one additional substituent group that does not contain fluorine atoms.

Each of the foregoing substituent groups optionally may be substituted unless expressly provided otherwise. The term “optionally substituted” refers to being substituted or unsubstituted. “Substituted” means that at least one hydrogen atom of the chemical structure or group is replaced with another terminal substituent group that is typically monovalent, provided that the designated atom's normal valence is not exceeded. When the substituent is oxo (i.e., O), then two geminal hydrogen atoms on the carbon atom are replaced with the terminal oxo group. It is further noted that the oxo group is bonded to carbon via a double bond to form a carbonyl (C═O), where the carbonyl group is represented herein as —C(O)—. Combinations of substituents or variables are permissible. Exemplary substituent groups that may be present on a “substituted” position include, but are not limited to, nitro (—NO₂), cyano (—CN), hydroxyl (—OH), oxo (O), amino (—NH₂), mono- or di-(C₁₋₆)alkylamino, alkanoyl (such as a C₂₋₆ alkanoyl group such as acyl), formyl (—C(O)H), carboxylic acid or an alkali metal or ammonium salt thereof; esters (including acrylates, methacrylates, and lactones) such as C₂₋₆ alkyl esters (—C(O)O-alkyl or —OC(O)-alkyl) and C₇₋₁₃ aryl esters (—C(O)O-aryl or —OC(O)-aryl); amido (—C(O)NR₂ wherein R is hydrogen or C₁₋₆ alkyl), carboxamido (—CH₂C(O)NR₂ wherein R is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₂₋₁₈ heterocycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₃₋₁₂ heterocycloalkyl, C₃₋₁₂ heteroaryl, C₁₋₆ alkyl sulfonyl (—S(O)₂-alkyl), C₆₋₁₂ arylsulfonyl (—S(O)₂-aryl), or tosyl (CH₃C₆H₄SO₂—). When a group is substituted, the indicated number of carbon atoms is the total number of carbon atoms in the group, excluding those of any substituents. For example, the group —CH₂CH₂CN is a cyano-substituted C₂ alkyl group.

As used herein, when a definition is not otherwise provided, a “divalent linking group” refers to a divalent group including one or more of —O—, —S—, —Te—, —Se—, —C(O)—, C(O)O—, —N(R′)—, —C(O)N(R′)—, —S(O)—, —S(O)₂—, —C(S)—, —C(Te)—, —C(Se)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein each R′ is independently hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. Typically, the divalent linking group includes one or more of —O—, —S—, —C(O)—, —N(R′)—, —S(O)—, —S(O)₂—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. More typically, the divalent linking group includes at least one of —O—, —C(O)—, —C(O)O—, —N(R′)—, —C(O)N(R′)—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃ heteroarylene, or a combination thereof, wherein R is hydrogen, substituted or unsubstituted C₁₋₁₀ alkyl, substituted or unsubstituted C₁₋₁₀ heteroalkyl, substituted or unsubstituted C₆₋₁₀ aryl, or substituted or unsubstituted C₃₋₃₀ heteroaryl.

As used herein, an “acid-labile group” refers to a group in which a bond is cleaved by the action of an acid, optionally and typically with thermal treatment, resulting in formation of a polar group, such as a carboxylic acid or alcohol group. When this type of group is a pendant on a polymer, the formation of the polar group occurs on the polymer. Optionally and typically with a moiety connected to the cleaved bond becoming disconnected from the polymer. In other systems, a non-polymeric compound may include an acid-labile group that may be cleaved by the action of an acid, resulting in formation of a polar group, such as a carboxylic acid or alcohol group on a cleaved portion of the non-polymeric compound. Such acid is typically a photo-generated acid with bond cleavage occurring during post-exposure baking (PEB); however, embodiments are not limited thereto, and, for example, such acid may be thermally generated.

Suitable acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-cleavable groups,” “acid-cleavable protecting groups,” “acid-labile protecting groups,” “acid-leaving groups,” “acid-decomposable groups,” and “acid-sensitive groups.”

The term “unsaturated bond” refers to a double or triple bond. The term “unsaturated” or “partially unsaturated” refers to a moiety that includes at least one double or triple bond. The term “saturated” refers to a moiety that does not contain a double or triple bond, i.e., the moiety only contains single bonds.

As used herein, the term “(meth)acrylic” includes both acrylic and methacrylic species (i.e., acrylic and methacrylic monomers), and the term “(meth)acrylate” includes both acrylate and methacrylate species (i.e., acrylate and methacrylate monomers).

Embedded barrier layers (EBLs) for photolithography were typically designed and developed for use in ArF (193 nm) immersion formulation technologies. EBLs are formed using lower surface-energy materials that are added directly to the photoresist composition and can segregate to the surface of the resulting film during spin-coating. These materials may be developer switchable, or base-switchable polymers that can switch from hydrophobic to hydrophilic during the development step. The application of base-switchable polymer additives for defect reduction in formulations other than ArF photoresist compositions has created the need for development of base-switchable polymer additives to further improve photolithographic performance at other exposure wavelengths, such as KrF and/or EUV.

The inventive polymer includes a first repeating unit having an aromatic group that is substituted with a hydroxyl group and a substituent group including a carbonyl group, and a second repeating unit that includes a base-labile group. In some aspects, the base-labile group includes a base-cleavable phenol ester containing one or more electron-withdrawing fluorine substituents. Prior to cleavage of the base-labile group, the material is relatively hydrophobic, whereas after cleavage the resulting hydroxy aromatic group(s) increase hydrophilicity of the material. The inventive polymer can be used as a base-switchable polymer in a photoresist composition to provide improved LWR and/or a decreased pseudo-Z factor. The inventive polymers also showed improved dissolution rates when applied as a film, soft baked, and subjected to developer treatment.

As aspect provides a polymer including a first repeating unit that is derived from a polymerizable compound that includes an aromatic group. The aromatic group is substituted with a first substituent group that includes an ethylenically unsaturated double bond. The aromatic group is substituted with a second substituent group that is a hydroxyl group. The aromatic group is also substituted with a third substituent group that includes a carbonyl group.

The first substituent group, the second substituent group, and the carbonyl group of the third substituent group are each bonded to a different carbon atom of the aromatic group. The polymer also includes a second repeating unit that includes a base-labile group. The first repeating unit and the second repeating unit of the polymer are structurally different from each other. It should be noted that the polymer may include one or more additional repeating units, beyond just the first repeating unit and the second repeating unit, where such additional repeating units are as described herein. Furthermore, while the aromatic group is substituted with the first substituent group, the second substituent group, and the third substituent group, it is to be understood that the aromatic group may be further substituted with other groups as described herein.

As used herein, an “aromatic group” refers to a C₆₋₆₀ aryl group or a C₃₋₆₀ heteroaryl group. The aromatic group may be monocyclic or polycyclic. When the C₆₋₆₀ aryl group is polycyclic, the ring or ring groups can be fused (such as naphthyl or the like), directly linked (such as biaryls, biphenyl, or the like), or a combination of fused and directly linked ring or ring groups (such as binaphthyl or the like). When the C₃₋₆₀ heteroaryl group is polycyclic, the ring or ring groups can be fused, directly linked, or a combination of fused and directly linked ring or ring groups.

The first repeating unit of the polymer is derived from a polymerizable compound including an aromatic group that is substituted with a first substituent group including an ethylenically unsaturated double bond, a second substituent group that is a hydroxyl group; and a third substituent group including a carbonyl group.

The first substituent group of the aromatic group includes an ethylenically unsaturated double bond. As used herein, an “ethylenically unsaturated double bond” refers to a vinyl-containing polymerizable group, and typically may be selected from substituted or unsubstituted C₂₋₂₀ alkenyl, substituted or unsubstituted norbornene, substituted or unsubstituted (meth)acrylic, substituted or unsubstituted vinyl ether, substituted or unsubstituted vinyl ketone, substituted or unsubstituted vinyl ester, or substituted or unsubstituted vinyl aromatic. The polymerizable group may form a ring with the aromatic group.

The second substituent group of the aromatic group is a hydroxyl (—OH) group. It is to be understood that the second substituent group may include one or more hydroxyl groups. In some aspects, the second substituent group can include from 1 to 9 hydroxyl groups, or from 1 to 5 hydroxyl groups, or from 1 to 3 hydroxyl groups, or 1 or 2 hydroxyl groups.

The third substituent group of the aromatic group includes a carbonyl group (—C(═O)—). It is to be understood that the third substituent group may include a carbonyl group, or may include 2 or more carbonyl groups that are the same or different from each other. In some aspects, the third substituent group may contain from 1 to 9 different carbonyl groups, or from 1 to 5 different carbonyl groups, or from 1 to 3 different carbonyl groups, or 2 different carbonyl groups, or a single carbonyl group (i.e., one carbonyl group). In some embodiments, the carbonyl group may be bonded directly to the aromatic group.

It is to be understood that the third substituent group that includes the carbonyl group further includes a hydrocarbon group that is optionally substituted with 1 to 3 heteroatoms. In some embodiments, the third substituent group including the carbonyl group may further include an acid labile group. Suitable acid-labile groups of the third substituent group include, for example, one or more of tertiary alkyl ester groups, secondary or tertiary aryl ester groups, secondary or tertiary ester groups having a combination of alkyl and aryl groups, tertiary alkoxy groups, acetal groups, or ketal groups.

In the polymerizable compound including the aromatic group, the first substituent group, the second substituent group, and the carbonyl group of the third substituent group are each bonded to a different carbon atom of the aromatic group.

In some embodiments, in the polymerizable compound including the aromatic group, the total number of second substituent groups and third substituent groups combined is 10 or less.

For example, in the polymerizable compound including the aromatic group, the total number of second substituent groups and third substituent groups combined may be 5 or less, or 4 or less, or 3 or less, or 2. In some embodiments, the number of second substituent groups and the number of third substituent groups, when combined, may be from 2 to 6, or from 2 to 4.

In some aspects, the first substituent group does not comprise an acid-labile group or an acid leaving group. In other words, in some aspects the polymerizable compound includes a polymerizable group (i.e., an ethylenically unsaturated double bond) that is not a tertiary alkyl ester group, a secondary or tertiary aryl ester group, a secondary or tertiary ester group having a combination of alkyl and aryl groups, a tertiary alkoxy group, an acetal group, or a ketal group.

For example, the first substituent group of the inventive compound may be (meth)acrylic or vinyl (e.g., substituted or unsubstituted C₂₋₁₂ alkenyl).

In some embodiments, the first repeating unit may be derived from a polymerizable compound of Formula (1):

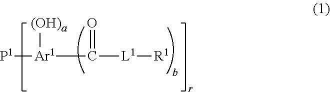

In Formula (1), P¹ includes a group including an ethylenically unsaturated double bond, wherein P¹ optionally forms a ring with Ar¹. Preferably, P¹ includes (meth)acrylic or substituted or unsubstituted C₂₋₁₂ alkenyl. In some embodiments, P¹ may further include a divalent linking group between the group including the ethylenically unsaturated double bond and Ar¹. For example, P¹ may include, in addition to the group including the ethylenically unsaturated double bond, a divalent linking group including one or more of substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted C₁₋₃₀ heteroarylene, —O—, —C(O)—, —C(O)O—, —C(O)NR^{1a}—, —N(R^{1b})—, or a combination thereof, wherein R^{1a} and R^{1b} are each independently hydrogen or C₁₋₆ alkyl.

In Formula (1), Ar¹ is substituted or unsubstituted C₆₋₆₀ aryl or substituted or unsubstituted C₃₋₆₀ heteroaryl, and each optionally may be further substituted with one or more of substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ alkylheteroaryl, or substituted or unsubstituted C₄₋₃₀ heteroarylalkyl.

It is to be understood that “further substituted” means the C₆₋₅₀ aryl group or the C₃₋₅₀ heteroaryl group is substituted as required by Formula (1) with at least the first substituent group (—P¹), the second substituent group (OH)ₐ, and the third substituent group (—C(O)-L¹-R¹), and the C₆₋₆₀ aryl group or the C₃₋₆₀ heteroaryl group optionally may be further substituted with one or more other substituent groups that are different from the first substituent group, the second substituent group, and the third substituent group. Typically, Ar¹ is a C₆₋₃₀ aryl group, and optionally may be further substituted with one or more of substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, or a combination thereof.

In Formula (1), a represents the number of hydroxyl groups that are bonded directly to the aromatic group (Ar¹), and is an integer greater than or equal to 1. In some aspects, a is an integer from 1 to 9, or an integer from 1 to 7, or an integer from 1 to 5, or an integer from 1 to 4, or an integer from 1 to 3, or 1 or 2. Preferably, a is 1 or 2.

In Formula (1), each L¹ is independently a single bond or a divalent linking group. For example, L¹ may be a divalent linking group including one or more of substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted C₁₋₃₀ heteroarylene, —O—, —C(O)—, —C(O)O—, —C(O)NR^{2a}—, or —N(R^{2b})—, wherein R^{2a} and R^{2b} are each independently hydrogen or C₁₋₆ alkyl.

In Formula (1), each R¹ is independently a substituted or unsubstituted C₁₋₃₀ alkyl, substituted or unsubstituted C₃₋₃₀ cycloalkyl, substituted or unsubstituted C₁₋₃₀ heteroalkyl, substituted or unsubstituted C₂₋₃₀ heterocycloalkyl, substituted or unsubstituted C₆₋₆₀ aryl, or substituted or unsubstituted C₃₋₆₀ heteroaryl.

In Formula (1), b represents the number of third substituent groups, where the third substituent groups may be defined by the moiety —C(O)-L²-R¹, and is an integer greater than or equal to 1. In some aspects, b is preferably an integer from 1 to 5, or an integer from 1 to 4, or an integer from 1 to 3, or 1 or 2. Preferably, b is an integer from 1 to 3.

In Formula (1), the sum of a and b (a+b) is an integer of 10 or less. For example, the sum of a and b (a+b) may be an integer from 2 to 8, or from 2 to 6, or from 2 to 4. Preferably, the sum of a and b (a+b) is an integer from 2 to 4.

In Formula (1), r is an integer of 1 or greater. For example, in Formula (1), r may be an integer from 1 to 5. Typically, r is 1.

In some embodiments, the moiety —C(O)-L—R¹ of Formula (1) comprises an acid labile group. Exemplary acid-labile groups include tertiary alkyl ester groups, secondary or tertiary aryl ester groups, secondary or tertiary ester groups having a combination of alkyl and aryl groups, tertiary alkoxy groups, acetal groups, or ketal groups.

In some embodiments, the moiety —C(O)-L¹-R¹ of Formula (1) may have a structure represented by one of Formula (2) or Formula (3):

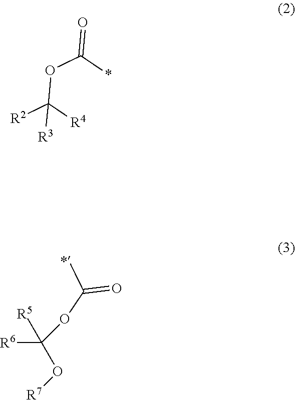

In Formula (2), R² to R⁴ are each independently hydrogen, substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl, provided that no more than one selected from R² to R⁴ is hydrogen, and provided that if one of R² to R⁴ is hydrogen, then at least one of the others from R² to R⁴ is substituted or unsubstituted C₆₋₂₀ aryl or substituted or unsubstituted C₃₋₂₀ heteroaryl. Each of R² to R⁴ may optionally further include a divalent linking group as part of its structure. For example, each of R² to R⁴ may further comprise as part of its structure one or more groups selected from —O—, —C(O)—, —C(O)O—, —S—, —S(O)₂—, —N(R^{3a})—, or —C(O)N(R^{3b})— wherein R^{3a} and R^{3b} are each independently hydrogen, substituted or unsubstituted C₁₋₂₀ alkyl, substituted or unsubstituted C₃₋₂₀ cycloalkyl, or substituted or unsubstituted C₃₋₂₀ heterocycloalkyl. Typically, R² to R⁴ are each independently hydrogen, substituted or unsubstituted C₁₋₁₀ alkyl, substituted or unsubstituted C₃₋₈ cycloalkyl, or substituted or unsubstituted C₆₋₁₄ aryl.

In Formula (3), R⁵ and R⁶ are each independently hydrogen, substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₆₋₂₀ aryl, or substituted or unsubstituted C₂₋₂₀ heteroaryl. Each of R⁵ and R⁶ may optionally further include a divalent linking group as part of its structure. For example, each of R⁵ and R⁶ may further comprise as part of its structure one or more groups selected from —O—, —C(O)—, —C(O)O—, —S—, —S(O)₂—, —N(R^{3a})—, or —C(O)N(R^{3b})—, wherein R^{3a} and R^{3b} are each independently hydrogen, substituted or unsubstituted C₁₋₂₀ alkyl, substituted or unsubstituted C₃₋₂₀ cycloalkyl, or substituted or unsubstituted C₃₋₂₀ heterocycloalkyl. Typically, R⁵ and R⁶ are each independently hydrogen, or substituted or unsubstituted C₁₋₁₀ alkyl.

In Formula (3), R⁷ is substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₆₋₂₀ aryl, or substituted or unsubstituted C₃₋₂₀ heteroaryl. R⁷ optionally may further comprise a divalent linking group as part of its structure. Typically, R⁷ may be substituted or unsubstituted C₁₋₁₀ alkyl, substituted or unsubstituted C₃₋₈ cycloalkyl, or substituted or unsubstituted C₆₋₁₄ aryl.

In Formula (2), any two of R², R³, or R⁴ together optionally may form a ring via a single bond or a divalent linking group, wherein the ring is substituted or unsubstituted. In Formula (3), R⁵ and R⁶ together optionally may form a ring via a single bond or a divalent linking group, wherein the ring is substituted or unsubstituted. In Formula (3), any one or more of R⁵ or R⁶ together with R⁷ optionally may form a ring via a single bond or a divalent linking group, wherein the ring is substituted or unsubstituted.

In Formulae (2) and (3), * and *′ each indicate a binding site to Ar¹.

Exemplary polymerizable compounds comprising an aromatic group include the

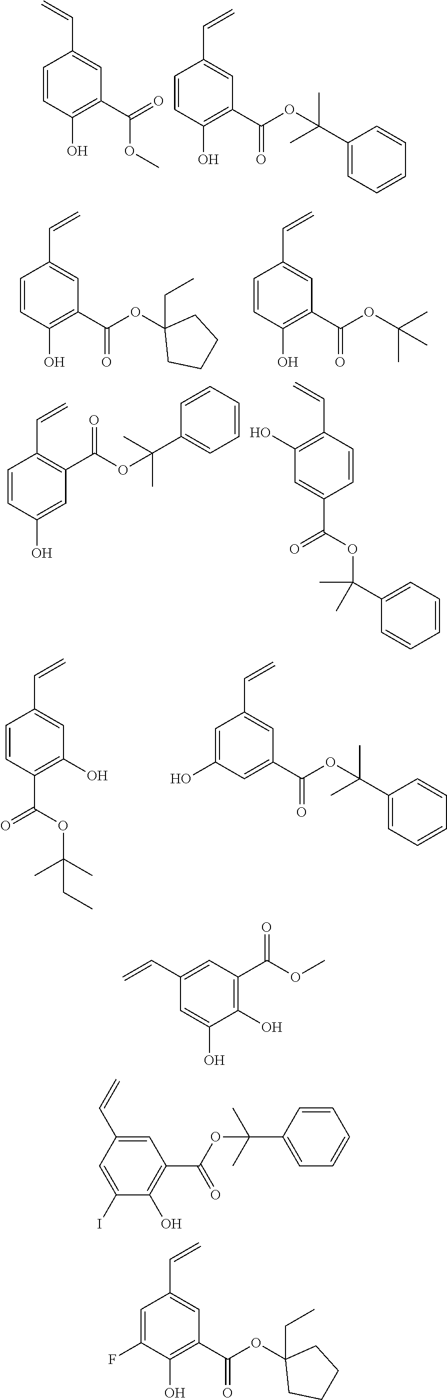

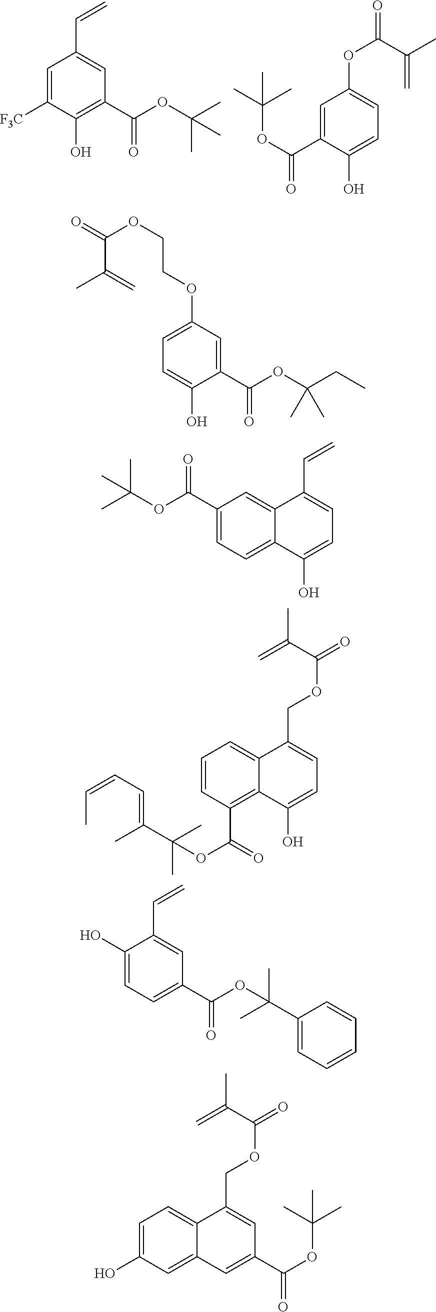

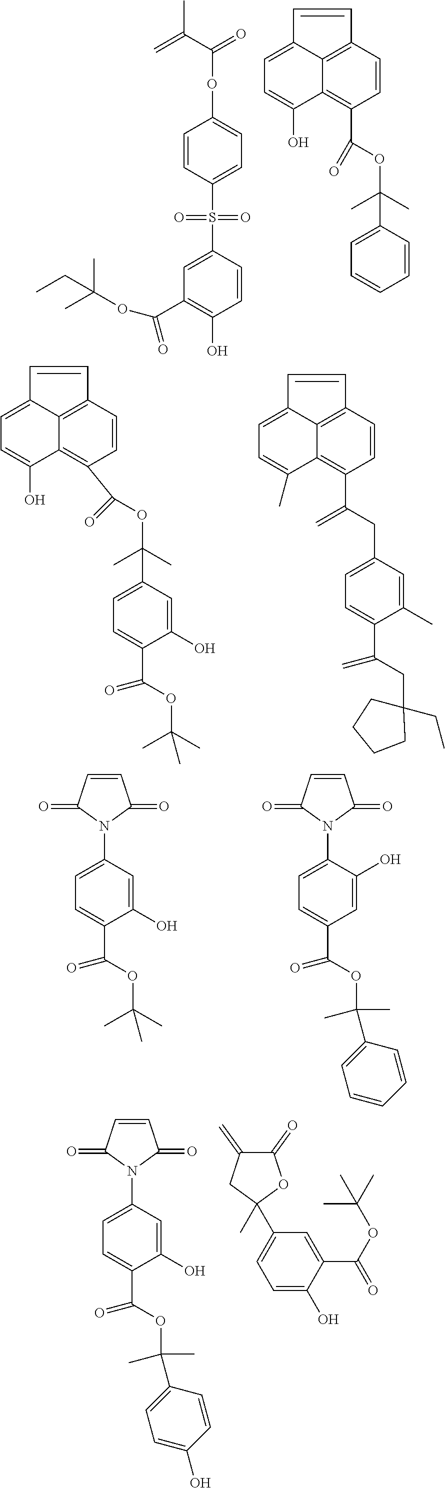

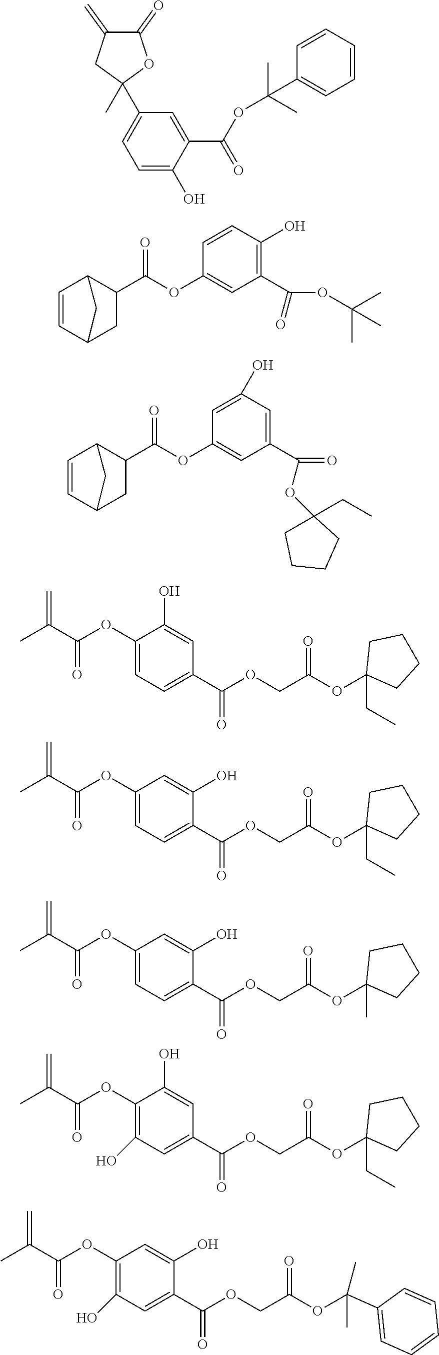

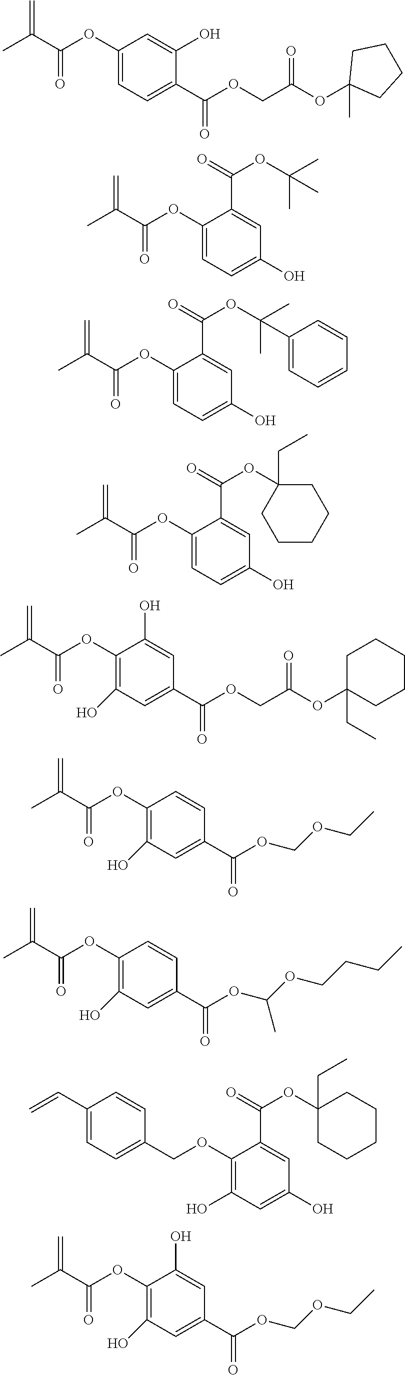

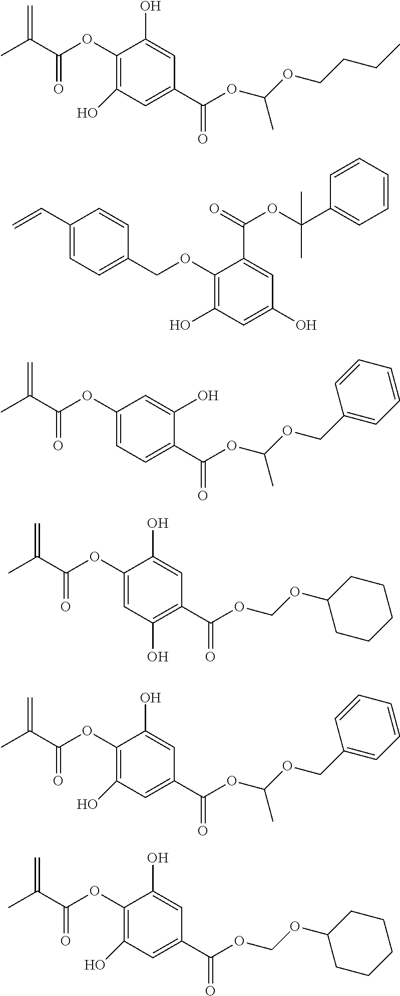

The inventive polymer also includes a second repeating unit, wherein the second repeating unit includes a base-labile group. As referred to herein, base-labile groups are functional groups that can undergo a cleavage reaction to provide polar groups such as hydroxyl, carboxylic acid, sulfonic acid, and the like, in the presence of an aqueous alkaline developer after exposure and post-exposure baking steps. The base-labile group will not react significantly (e.g., will not undergo a bond-breaking reaction) prior to a development step of the photoresist composition that comprises the base-labile group. Thus, for instance, a base-labile group will be substantially inert during pre-exposure soft-bake, exposure, and post-exposure bake steps. By “substantially inert” it is meant that ≤5%, typically ≤1%, of the base-labile groups (or moieties) will decompose, cleave, or react during the pre-exposure soft-bake, exposure, and post-exposure bake steps. The base-labile group is reactive under typical photoresist development conditions using, for example, an aqueous alkaline photoresist developer such as a 0.26 normal (N) aqueous solution of tetramethylammonium hydroxide (TMAH). For example, a 0.26 N aqueous solution of TMAH may be used for single puddle development or dynamic development, e.g., where the 0.26 N TMAH developer is dispensed onto an imaged photoresist layer for a suitable time such as 10 to 120 seconds (s). An exemplary base-labile group is an ester group, typically a fluorinated ester group or a fluorinated alcohol group. In some embodiments, the base-labile group may include a fluorinated alkyl ester group, a fluorinated aryl ester group, or a hexafluoroalcohol group.

The second repeating unit may include one or more base-labile groups. For example, in some embodiments, the second repeating unit may include 2 or more base-labile groups, for example a second repeating unit comprising 2 or 3 base-labile groups. Each of the base-labile groups in the second repeating unit may be the same or different.

In some embodiments, the second repeating unit may be derived from one or more polymerizable compounds that each includes a polymerizable group that includes an ethylenically unsaturated double bond; and a base-labile group that includes a structure represented by Formula (4):

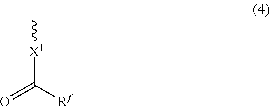

In Formula (4), X¹ is O, S, or —N(R^{c})—, wherein R^{c} is hydrogen or C₁₋₆ alkyl. Typically, X¹ is O.

In Formula (4), R^{f} is a substituted or unsubstituted fluoroalkyl group comprising a fluorine atom or a fluoroalkyl group bonded to a carbon atom at an alpha position with respect to the carbonyl group (i.e., the carbon atom bonded to the carbonyl (—C(O)—) is substituted with at least one fluorine atom or a fluoroalkyl group). In some embodiments, each R^{f} is independently substituted or unsubstituted C₁₋₂₀ fluoroalkyl, provided that the carbon atom bonded to the carbonyl (—C(O)—) is substituted with at least one fluorine atom or a fluoroalkyl group. For example, R^{f} may be a substituted or unsubstituted C₁₋₂₀, C₁₋₁₀, C₁₋₅, C₁₋₄, or C₁₋₃ fluoroalkyl group. Typically, R^{f} is —CF₃, —CH₂CF₃, —CF₂CH₃, —CF₂CF₂H, —C₂F₅, —C₃F₇, or —C₄F₉.

For example, the second repeating unit may be derived from one or more polymerizable compounds of Formula (5):

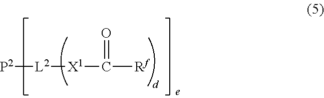

In Formula (5), P² is a group including an ethylenically unsaturated double bond, wherein P² optionally forms a ring with L².

In Formula (5), L² is a single bond or a linking group. Typically, L² is a linking group including one or more of substituted or unsubstituted C₁₋₂₀ alkylene, substituted or unsubstituted C₃₋₂₀ cycloalkylene, substituted or unsubstituted C₆₋₃₀ arylene, substituted or unsubstituted C₃₋₃₀ heteroarylene, —C(O)—, or —C(O)O—. Typically, L² may be a linking group including one or more of substituted or unsubstituted C₁₋₂₀ alkylene, or substituted or unsubstituted C₆₋₃₀ arylene.

In some embodiments, L² may include an aromatic group that is substituted with at least one halogen, for example, a C₆₋₃₀ arylene that is substituted with at least one halogen or a C₃₋₃₀ heteroarylene that is substituted with at least one halogen. For example, L² may include an aromatic group that is substituted with 1 to 9 halogen atoms, or 1 to 6 halogen atoms, or 1 to 4 halogen atoms, or 1 to 3 halogen atoms, or 1 to 2 halogen atoms. Preferably, the at least one halogen atom is iodine. As used herein, “an aromatic group that is substituted with at least one halogen” refers to an aromatic group that is directly bonded to at least one halogen atom.

In Formula (5), each X¹ is independently O, S, or —N(R′)—, wherein R^{f} is hydrogen or C₁₋₆ alkyl. Typically, X¹ is O.

In Formula (5), each R^{f} is a substituted or unsubstituted fluoroalkyl group comprising a fluorine atom or a fluoroalkyl group bonded to a carbon atom at an alpha position with respect to the carbonyl group (i.e., the carbon atom bonded to the carbonyl (—C(O)—) is substituted with at least one fluorine atom or a fluoroalkyl group). In some embodiments, each R^{f} is independently substituted or unsubstituted C₁₋₂₀ fluoroalkyl, provided that the carbon atom bonded to the carbonyl (—C(O)—) is substituted with at least one fluorine atom or a fluoroalkyl group. For example, R^{f} may be a substituted or unsubstituted C₁₋₂₀, C₁₋₁₀, C₁₋₅, C₁₋₄, or C₁₋₃ fluoroalkyl group. Typically, R^{f} is —CF₃, —CH₂CF₃, —CF₂CH₃, —CF₂CF₂H, —C₂F₅, —C₃F₇, or —C₄F₉.

In Formula (5), each d is an integer of 1 or greater. For example, each d may be an integer from 1 to 3.

In Formula (5), e is an integer of 1 or greater. Preferably, e is 1 or 2. Typically, e is 1.

Exemplary polymerizable compounds of Formula (5) include the following:

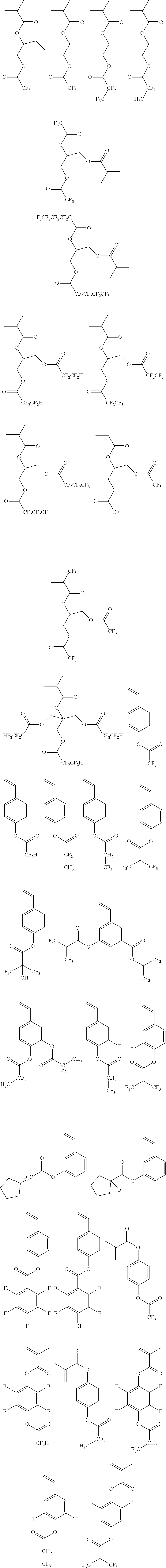

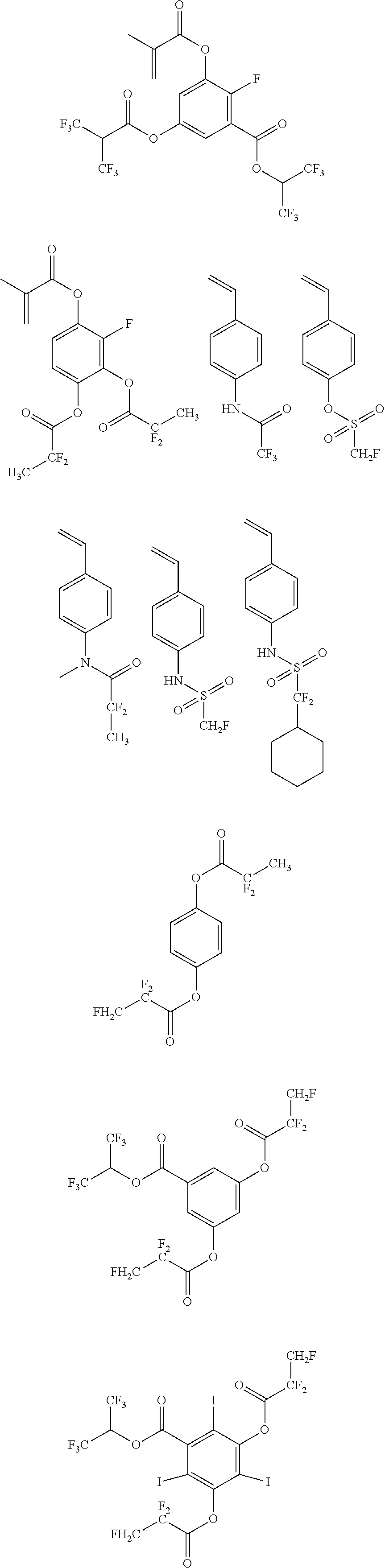

The first repeating unit is typically present in the polymer in an amount from 0.1 to 30 mole percent (mol %), more typically from 1 to 25 mol %, still more typically from 5 to 20 mol %, based on total repeating units in the polymer.

The second repeating unit is typically present in the polymer in an amount from 0.1 to 95 mol %, more typically from 20 to 95 mol %, still more typically from 50 to 90 mol %, based on total repeating units in the polymer.

The polymer may optionally further include one or more additional repeating units different from the first repeating unit and the second repeating unit. For example, the second may optionally include one or more additional repeating units as described below. The one or more additional units if present in the polymer may be used in an amount of up to 70 mol %, and typically from 3 to 50 mol %, based on total repeating units in the polymer.

In one or more embodiments, the polymer may include an acid-labile repeating unit derived from a monomer represented by one or more of Formulae (6), (7), (8), (9), or (10):

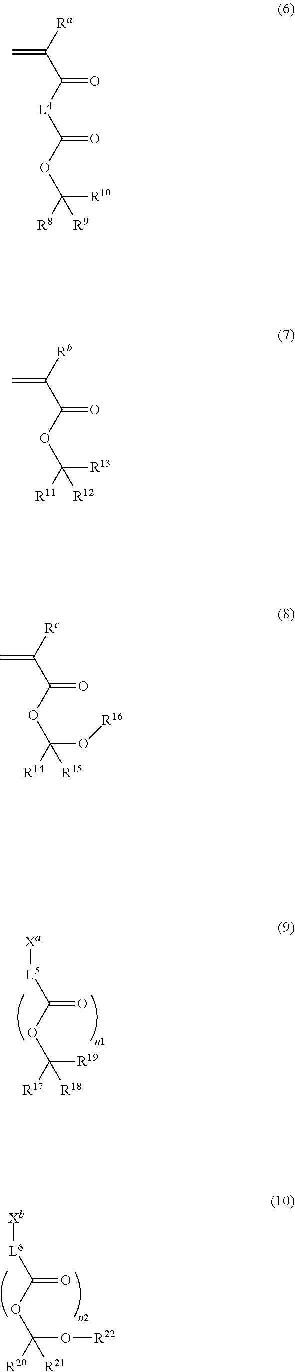

In Formulae (6), (7) and (8), R^{a}, R^{b}, and R^{c} may each independently be hydrogen, fluorine, cyano, or substituted or unsubstituted C₁₋₁₀ alkyl. Preferably, R^{a}, R^{b}, and R^{c} may each independently be hydrogen, fluorine, or substituted or unsubstituted C₁₋₅ alkyl, typically methyl.

In Formula (6), L⁴ is a divalent linking group. For example, L⁴ may include 1 to 10 carbon atoms and at least one heteroatom. In a typical example, L⁴ may be —OCH₂—, —OCH₂CH₂O—, or —N(R^{6a})—, wherein R^{6a} is hydrogen or C₁₋₆ alkyl.

In Formulae (6) and (7), R⁸ to R¹³ are each independently hydrogen, substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₃₋₂₀ heteroaryl, provided that no more than one of R⁸ to R¹⁰ may be hydrogen, and that no more than one of R¹¹ to R¹³ may be hydrogen, and provided that if one of R⁸ to R¹⁰ is hydrogen, then at least one of the others from R⁸ to R¹⁰ is substituted or unsubstituted C₆₋₂₀ aryl or substituted or unsubstituted C₃₋₂₀ heteroaryl, and if one of R¹¹ to R¹³ is hydrogen, then at least one of the others from R¹¹ to R¹³ is substituted or unsubstituted C₆₋₂₀ aryl or substituted or unsubstituted C₃₋₂₀ heteroaryl. Preferably, R⁸ to R¹³ are each independently substituted or unsubstituted C₁₋₆ alkyl or substituted or unsubstituted C₃₋₁₀ cycloalkyl. Each of R¹ to R¹³ may optionally further comprise a divalent linking group as part of their structure.

For example, any one or more of R⁸ to R¹³ may be independently a group of the formula —CH₂C(O)CH₍₃₋ₙ₎Yₙ, or —CH₂C(O)OCH₍₃₋ₙ₎Yₙ, where each Y is independently substituted or unsubstituted C₃₋₁₀ heterocycloalkyl and n is 1 or 2. For example, each Y may be independently substituted or unsubstituted C₃₋₁₀ heterocycloalkyl including a group of the formula —O(C^{a1})(C^{a2})O—, wherein C^{a1} and C^{a2} are each independently hydrogen or substituted or unsubstituted alkyl, and where C^{a1} and C^{a2} together optionally form a ring.

In Formula (6), any two of R⁸ to R¹⁰ together optionally may form a ring, which may further include a divalent linking group as part of its structure, and wherein the ring may be substituted or unsubstituted. In Formula (7), any two of R¹¹ to R¹³ together optionally may form a ring, which may further include a divalent linking group as part of its structure, wherein the ring group may be substituted or unsubstituted.

In Formulae (8) and (10), R¹⁴, R¹⁵, R²⁰, and R²¹ each independently may be hydrogen, substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₆₋₂₀ aryl, or substituted or unsubstituted C₃₋₂₀ heteroaryl; and R¹⁶ and R²² are each independently substituted or unsubstituted C₁₋₂₀ alkyl, substituted or unsubstituted C₃₋₂₀ cycloalkyl, or substituted or unsubstituted C₃₋₂₀ heterocycloalkyl. Preferably, R¹⁴, R¹⁵, R²⁰, and R²¹ each independently may be hydrogen, substituted or unsubstituted C₁₋₂₀ alkyl, substituted or unsubstituted C₃₋₂₀ cycloalkyl, or substituted or unsubstituted C₃₋₂₀ heterocycloalkyl. Each of R¹⁴, R¹⁵, R²⁰, and R²¹ may optionally further comprise a divalent linking group as part of their structure.

In Formula (8), any two of R¹⁴ to R¹⁶ together optionally may form a ring, which may further include a divalent linking group as part of its structure, wherein the ring group may be substituted or unsubstituted.

In Formula (9), R¹⁷ to R¹⁹ may be each independently be substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₆₋₂₀ aryl, or substituted or unsubstituted C₃₋₂₀ heteroaryl, provided that no more than one of R¹⁷ to R¹⁹ may be hydrogen and provided that if one of R¹⁷ to R¹⁹ is hydrogen, then at least one of the others from R¹⁷ to R¹⁹ is substituted or unsubstituted C₆₋₂₀ aryl or substituted or unsubstituted C₃₋₂₀ heteroaryl. Each of R¹⁷ to R¹⁹ may optionally further comprise a divalent linking group as part of their structure.

For example, any one or more of R¹⁷ to R¹⁹ may be independently a group of the formula —CH₂C(O)CH₍₃₋ₙ₎Yₙ, or —CH₂C(O)OCH₍₃₋ₙ₎Yₙ, where each Y is independently substituted or unsubstituted C₃₋₁₀ heterocycloalkyl and n is 1 or 2. For example, each Y may be independently substituted or unsubstituted C₃₋₁₀ heterocycloalkyl including a group of the formula —O(C^{a1})(C^{a2})O—, wherein C^{a1} and C^{a2} are each independently hydrogen or substituted or unsubstituted alkyl, and where C^{a1} and C^{a2} together optionally form a ring.

In Formula (9), any two of R¹⁷ to R¹⁹ together optionally form a ring, which may further include a divalent linking group as part of its structure, wherein the ring group may be substituted or unsubstituted.

In Formulae (9) and (10), X^{a} and X^{b} are each independently a polymerizable group comprising an ethylenically unsaturated double bond, preferably (meth)acrylate or C₂ alkenyl.

In Formulae (9) and (10), L⁵ and L⁶ are each independently a single bond or a divalent linking group, provided that L⁵ is not a single bond when X^{a} is C₂ alkenyl and that L⁶ is not a single bond when X^{b} is C₂ alkenyl. Preferably, L⁵ and L⁶ are each independently substituted or unsubstituted C₆₋₃₀ arylene or substituted or unsubstituted C₆₋₃₀ cycloalkylene. In Formulae (9) and (10), n1 is 0 or 1 and n2 is 0 or 1. It is to be understood that when n1 is 0, the L⁵ group is connected directly to the oxygen atom. It is to be understood that when n2 is 0, the L⁶ group is connected directly to the oxygen atom.

In Formula (10), any two of R²⁰ to R²² together optionally may form a ring, which may further include a divalent linking group as part of its structure, wherein the ring group may be substituted or unsubstituted.

In some aspects, each of R¹ to R²² optionally may further include as part of their structure one or more divalent linking groups selected from —O—, —C(O)—, —C(O)O—, —S—, —S(O)₂—, —N(R′)—, or —C(O)N(R′)—, wherein R′ may be hydrogen, substituted or unsubstituted C₁₋₂₀ alkyl, substituted or unsubstituted C₃₋₂₀ cycloalkyl, or substituted or unsubstituted C₃₋₂₀ heterocycloalkyl.

Exemplary monomers of Formula (6) include one or more of the following:

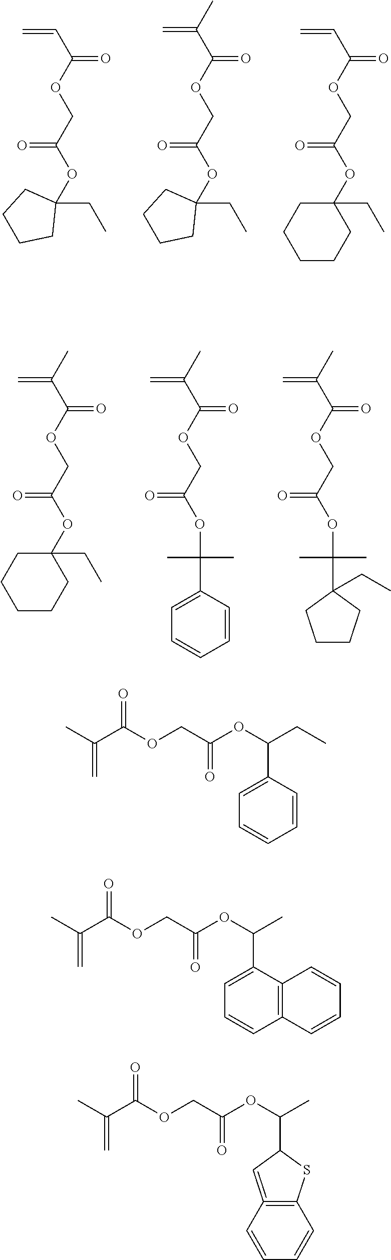

Exemplary monomers of Formula (7) include one or more of the following:

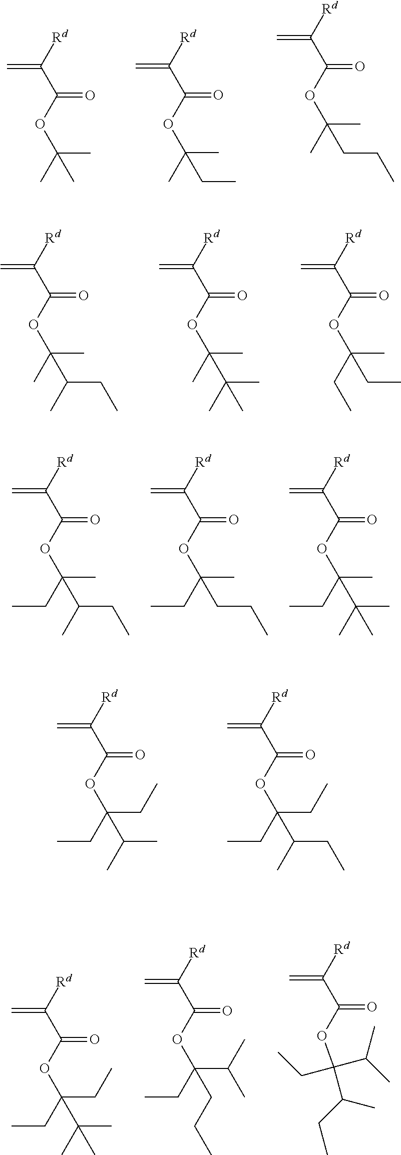

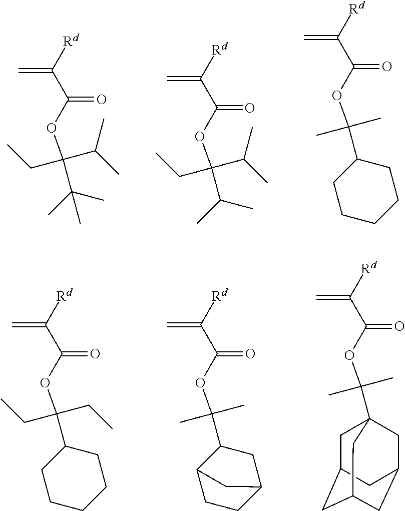

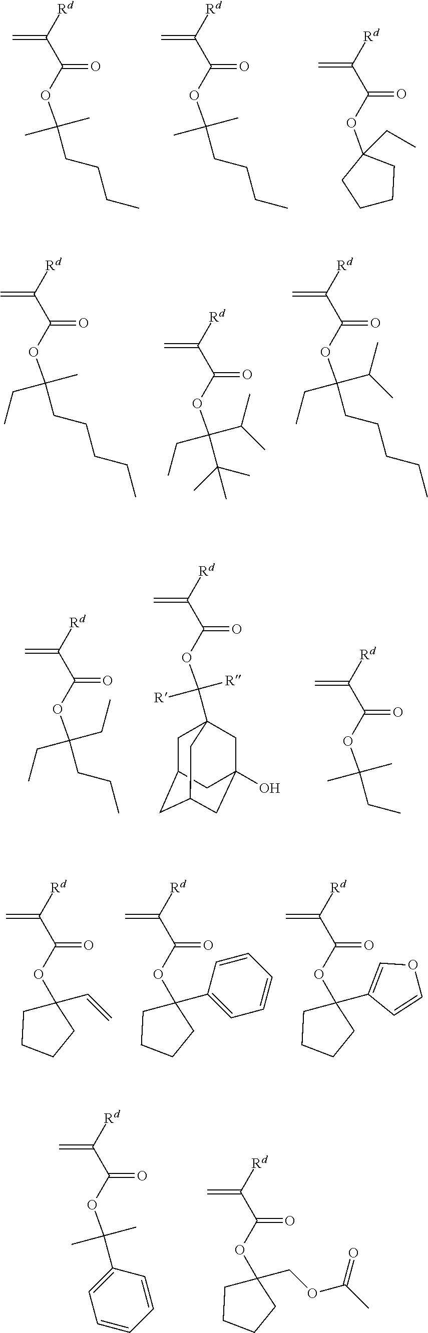

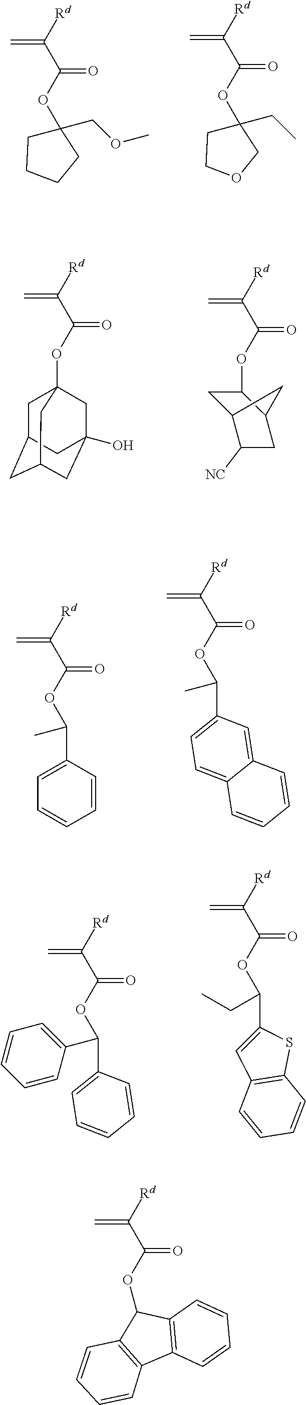

wherein R^{d} is as defined herein for R^{b} in Formula (7); and R′ and R″ are each independently substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₃₋₂₀ heteroaryl.

Exemplary monomers of Formula (8) include one or more of the following:

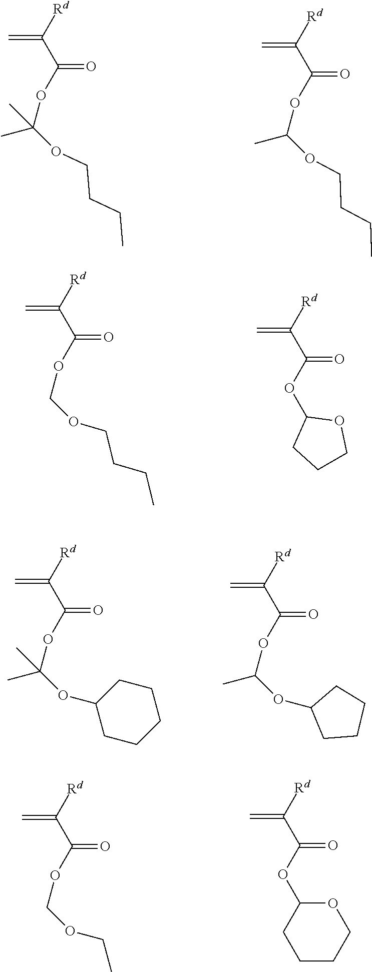

wherein R^{d} is as defined above for R^{c}.

Exemplary monomers of Formula (9) include one or more of the following:

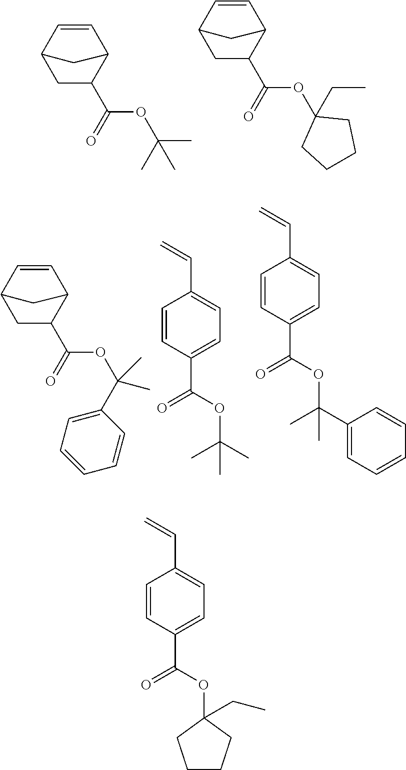

Exemplary monomers of Formula (10) include one or more of the following:

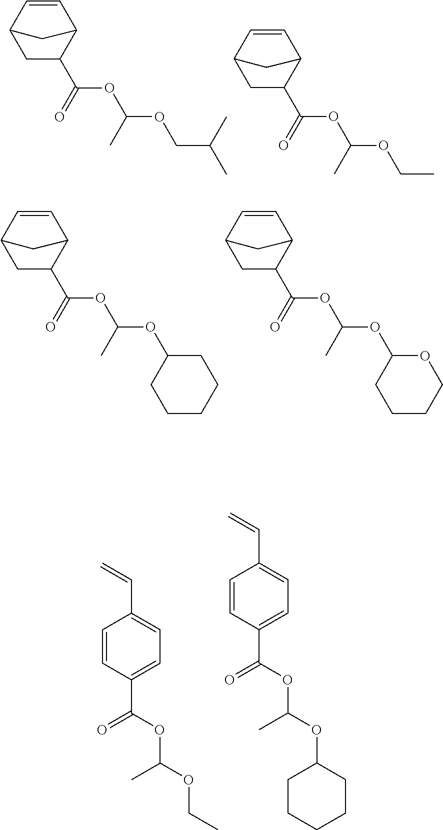

In some aspects, the polymer may have an acid-labile repeating unit that is derived from one or more monomers having a cyclic acetal or cyclic ketal group, for example, having one or more of the following structures:

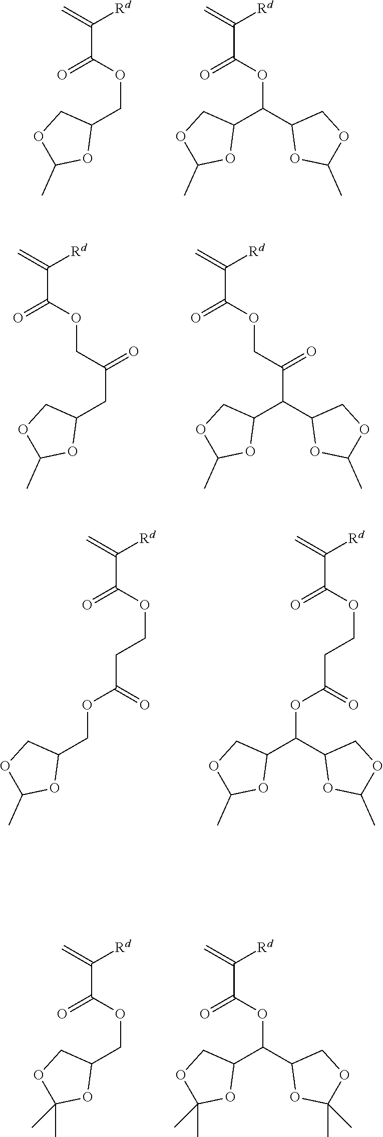

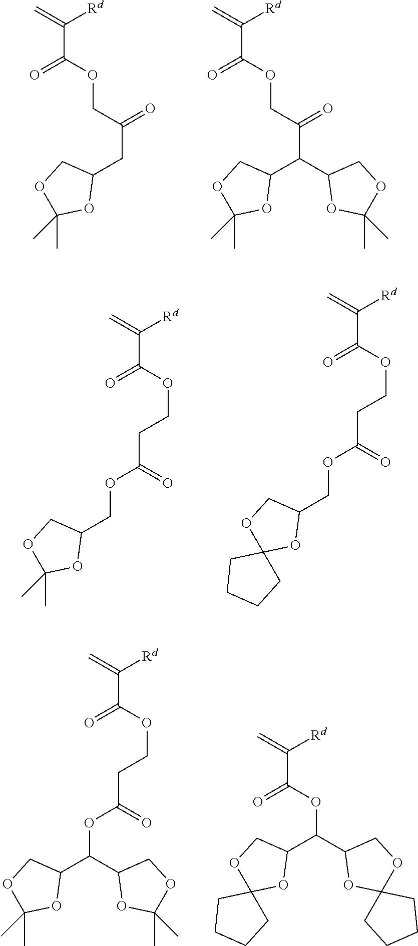

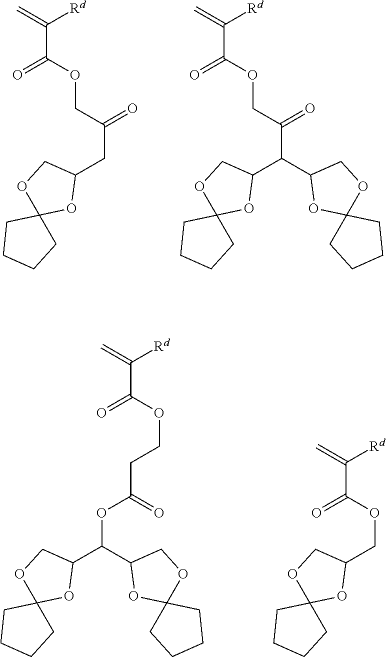

wherein R^{d} is as defined above for R^{a}.

In some aspects, the polymer may have a repeating unit having an acid-labile group that comprises a tertiary alkoxy group, for example, one or more monomers of the following:

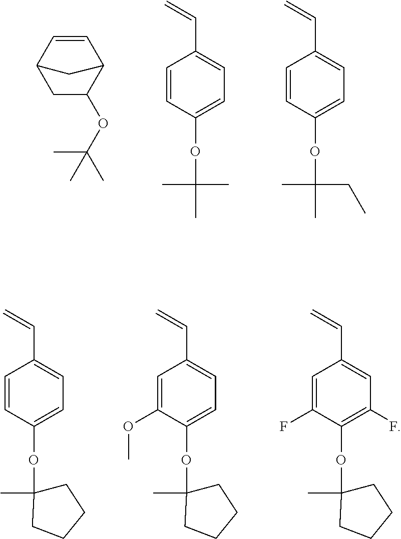

When present, the repeating unit having an acid-labile group, and that is different from first repeating unit, is typically present in the polymer in an amount from 25 to 65 mol %, more typically from 30 to 50 mol %, still more typically from 30 to 45 mol %, based on total repeating units in the polymer.

In some aspects, the polymer may further include a repeating unit comprising a polar group, where the polar group is pendant to the backbone of the polymer. For example, the polar group can be a lactone group, a hydroxy aryl group, a carboxylic acid group, or a combination thereof, but embodiments are not limited thereto.

In one or more embodiments, the polymer may further include a repeating unit derived from one or more lactone-containing monomers of Formula (11):

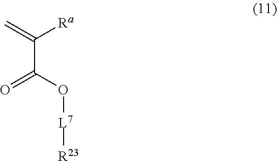

wherein R^{a} is hydrogen, fluorine, cyano, or substituted or unsubstituted C₁₋₁₀ alkyl.

In Formula (11), L⁷ is a single bond or a divalent linking group. Exemplary divalent linking groups for L⁷ include one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, —O—, —C(O)—, —C(O)O—, —S—, —S(O)₂—, —N(R^{11a})—, or —C(O)N(R^{11b})—, wherein R^{11a} and R^{11b} may be each independently hydrogen, substituted or unsubstituted C₁₋₂₀ alkyl, substituted or unsubstituted C₃₋₂₀ cycloalkyl, or substituted or unsubstituted C₃₋₂₀ heterocycloalkyl.

It is to be understood that when L⁷ is a single bond, the moiety —R²³ is directly connected to the oxygen atom adjacent to the carbonyl group (i.e., —C(O)O—R²³).

In Formula (11), R²³ is a substituted or unsubstituted C₄₋₂₀ lactone-containing group or a substituted or unsubstituted C₄₋₂₀ sultone-containing group. The C₄₋₂₀ lactone-containing group and the C₄₋₂₀ sultone-containing group may be monocyclic, polycyclic, or fused polycyclic.

Exemplary monomers of Formula (11) may include one or more of the following:

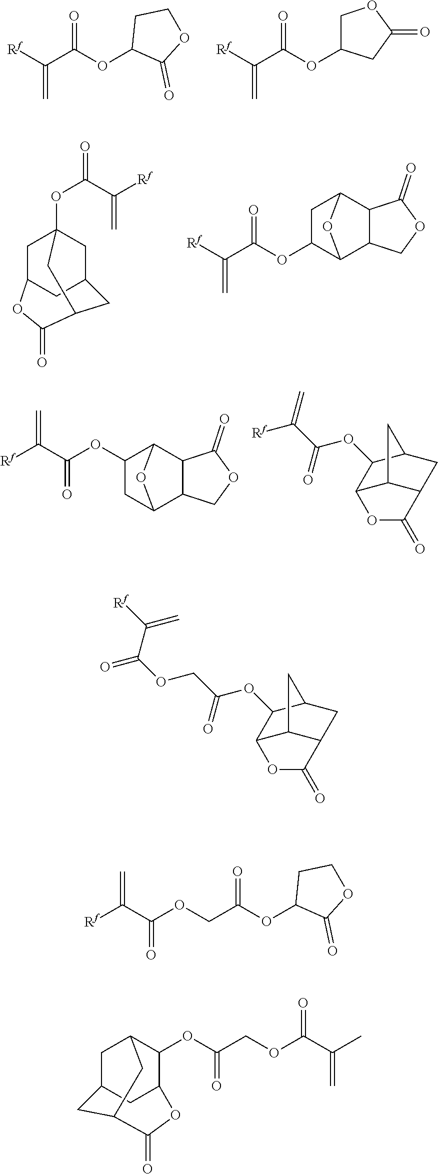

wherein R^{f} is as defined for Rain Formula (11).

In some aspects, the repeating unit comprising a polar group may be a repeating unit that is base-soluble and/or that has a pKa of less than or equal to 12. For example, such repeating units may be derived from one or more monomers of Formulae (12), (13), or (14):

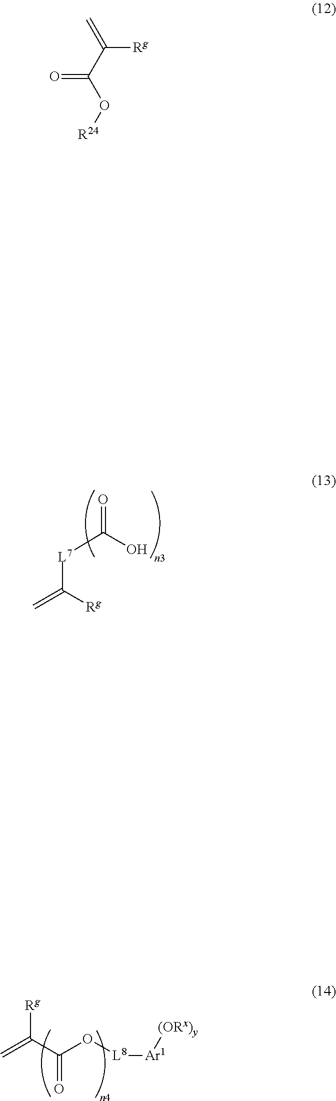

wherein each R^{g} may be hydrogen, fluorine, cyano, or substituted or unsubstituted C₁₋₁₀ alkyl. Preferably, R^{g} may be hydrogen, fluorine, or substituted or unsubstituted C₁₋₅ alkyl, typically methyl.

In Formula (12), R²⁴ may be substituted or unsubstituted C₁₋₁₀₀ or C₁₋₂₀ alkyl, typically C₁₋₁₂ alkyl; substituted or unsubstituted C₃₋₃₀ or C₃₋₂₀ cycloalkyl; or substituted or unsubstituted poly(C₁₋₃ alkylene oxide). Preferably, the substituted C₁₋₁₀₀ or C₁₋₂₀ alkyl, the substituted C₃₋₃₀ or C₃₋₂₀ cycloalkyl, and the substituted poly(C₁₋₃ alkylene oxide) are substituted with one or more of halogen, a fluoroalkyl group such as a C₁₋₄ fluoroalkyl group, typically fluoromethyl, a sulfonamide group —NH—S(O)₂—Y¹ where Y¹ is F or C₁₋₄ perfluoroalkyl (e.g., —NHSO₂CF₃), or a fluoroalcohol group (e.g., —C(CF₃)₂OH).

In Formula (13), L⁸ represents a single bond or a multivalent linking group chosen, for example, from optionally substituted aliphatic, such as C₁₋₆ alkylene or C₃₋₂₀ cycloalkylene, and aromatic hydrocarbons, and combinations thereof, optionally with one or more linking moieties chosen from —O—, —C(O)—, —C(O)O—, —S—, —S(O)₂—, —NR^{13a}—, or —C(O)N(R^{13a})—, wherein R^{13a} is chosen from hydrogen and optionally substituted C₁₋₁₀ alkyl. For example, the polymer may further include a repeating unit derived from one or more monomers of Formula (12) wherein L¹ is a single bond or a multivalent linking group selected from substituted or unsubstituted C₁₋₂₀ alkylene, typically C₁₋₆ alkylene; substituted or unsubstituted C₃₋₂₀ cycloalkylene; typically, C₃₋₁₀ cycloalkylene; and substituted or unsubstituted C₆₋₂₄ arylene.

In Formula (13), n3 is an integer from 1 to 5, typically 1. It is to be understood that when n3 is 1, the group L⁸ is a divalent linking group. It is to be understood that when n3 is 2, the group L⁸ is a trivalent linking group. Similarly, it is to be understood that when n3 is 3, the group L⁸ is a tetravalent linking group; when n3 is 4, the group L⁸ is a pentavalent linking group; and when n3 is 5, the group L⁸ is a hexavalent linking group. Accordingly, in the context of Formula (13), the term “multivalent linking group” refers to any of a divalent, trivalent, tetravalent, pentavalent, and/or hexavalent linking groups. In some aspects, when n is 2 or greater, the carboxylic acid groups (—C(O)OH) may be connected to the same atom of the linking group L⁸. In other aspects, when n is 2 or greater, the carboxylic acid groups (—C(O)OH) may be connected to different atoms of the linking group L⁸.

In Formula (14), L⁹ represents a single bond or a divalent linking group. Preferably, L⁹ may be a single bond, substituted or unsubstituted C₆₋₃₀ arylene, or substituted or unsubstituted C₆₋₃₀ cycloalkylene.

In Formula (14), n4 is 0 or 1. It is to be understood that when n4 is 0, the moiety represented by —OC(O)— is a single bond such that L⁹ is directly connected to the alkenyl (vinylic) carbon atom.

In Formula (14), Ar³ is a substituted C₅₋₆₀ aromatic group that optionally includes one or more aromatic ring heteroatoms chosen from N, O, S, or a combination thereof, wherein the aromatic group may be monocyclic, non-fused polycyclic, or fused polycyclic. When the C₅₋₆₀ aromatic group is polycyclic, the ring or ring groups may be fused (such as naphthyl or the like), non-fused, or a combination thereof. When the polycyclic C₅₋₆₀ aromatic group is non-fused, the ring or ring groups may be directly linked (such as biaryls, biphenyl, or the like) or may be bridged by a heteroatom (such as triphenylamino or diphenylene ether). In some aspects, the polycyclic C₅₋₆₀ aromatic group may include a combination of fused rings and directly linked rings (such as binaphthyl or the like).

In Formula (14), y may be an integer from 1 to 12, preferably from 1 to 6, and typically from 1 to 3. Each R^{x} may independently be hydrogen or methyl.

Non-limiting examples of monomers of Formulae (12), (13), and/or (14) include one or more of the following:

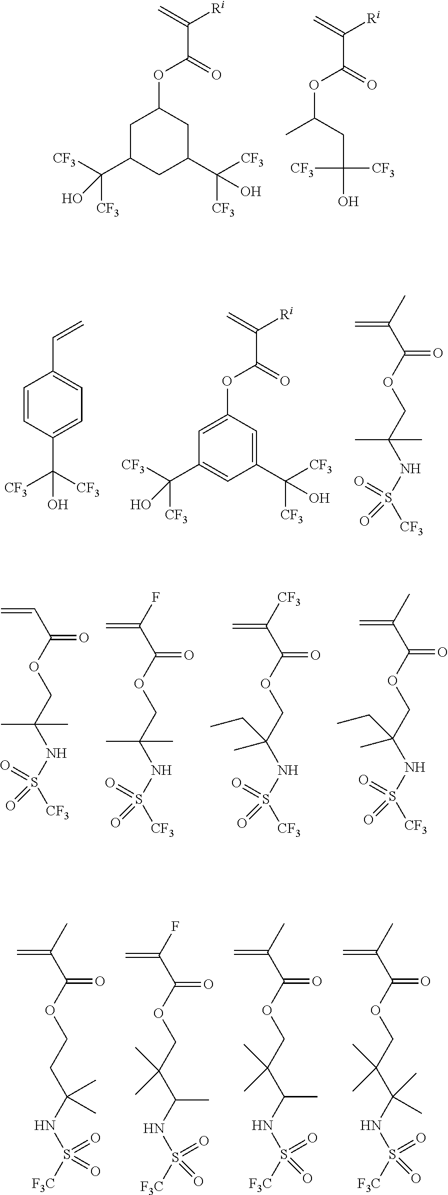

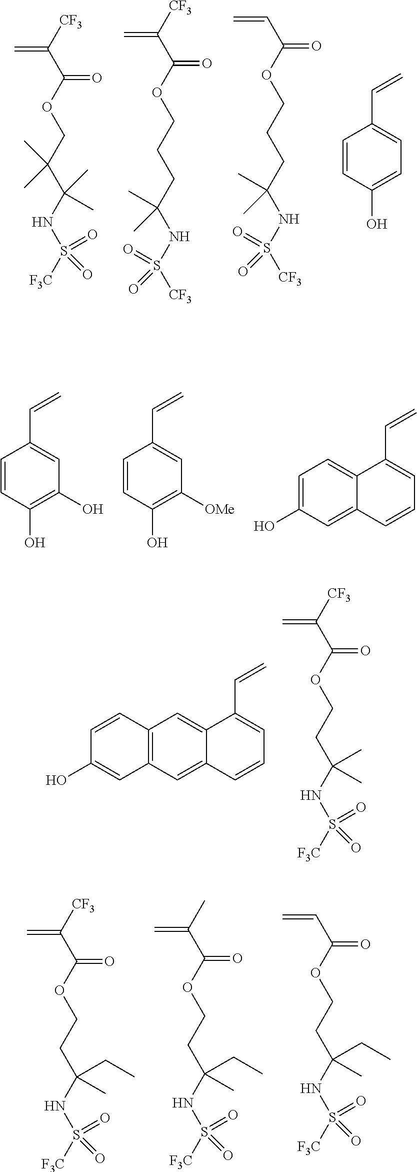

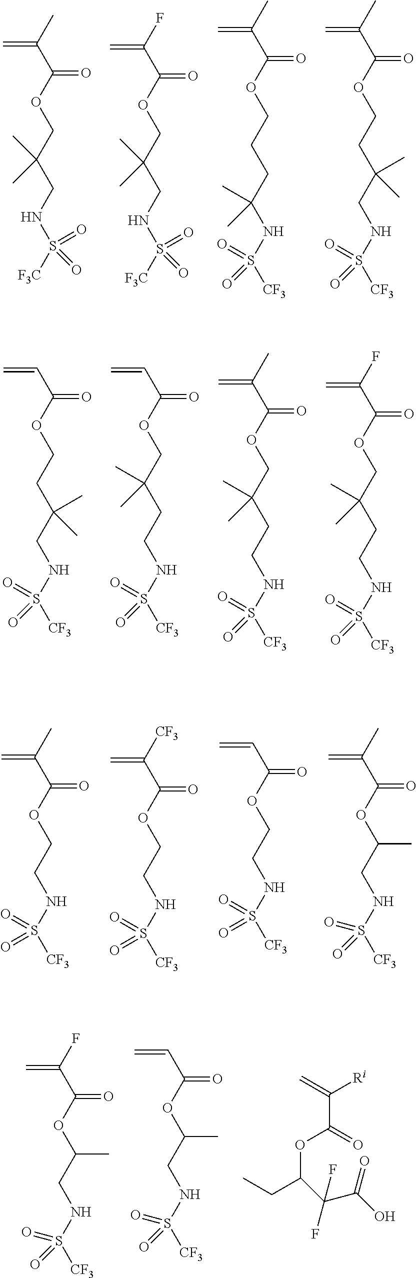

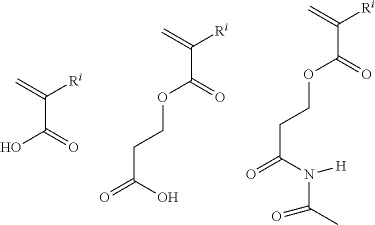

wherein Y¹ is as described above, and Rⁱ is as defined for R^{g} in Formulae (12)-(14).

When present, the polymer typically comprises a repeating unit comprising a polar group (pendant to a backbone of the polymer) in an amount from 1 to 60 mol %, typically from 5 to 50 mol %, more typically from 5 to 40 mol %, based on total repeating units in the polymer.

Non-limiting exemplary polymers include one or more of the following:

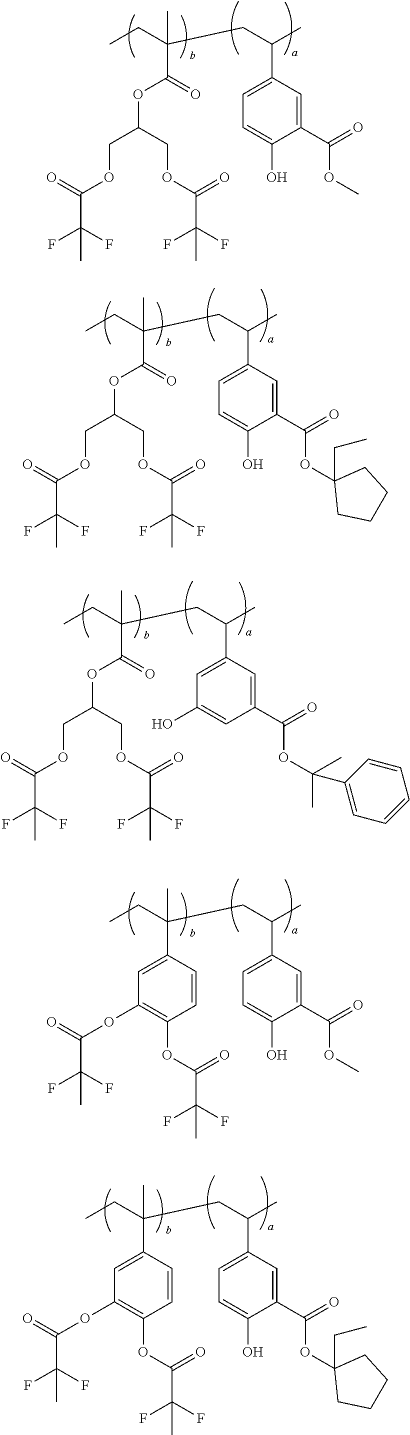

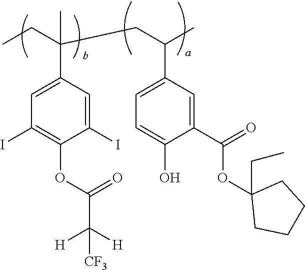

wherein a and b represent the mole fractions for the respective repeating units of the polymer.

The polymer typically has a weight average molecular weight (M_{w}) from 1,000 to 50,000 Dalton (Da), preferably from 2,000 to 30,000 Da, more preferably 4,000 to 25,000 Da, and still more preferably from 5,000 to 25,000 Da. The polydispersity index (PDI) of the polymer, which is the ratio of M_{w} to number average molecular weight (Mₙ) is typically from 1.1 to 3, and more typically from 1.1 to 2. Molecular weight values are determined by gel permeation chromatography (GPC) using polystyrene standards.

The polymer may be prepared using any suitable method(s) in the art. For example, one or more monomers corresponding to the repeating units described herein may be combined, or fed separately, using suitable solvent(s) and initiator, and polymerized in a reactor. For example, the polymer may be obtained by polymerization of the respective monomers under any suitable conditions, such as by heating at an effective temperature, irradiation with actinic radiation at an effective wavelength, or a combination thereof.

Also provided are photoresist compositions including the inventive polymer, a photoacid generator (PAG), and a solvent.

Suitable PAGs can generate an acid that, during post-exposure bake (PEB), causes cleavage of acid-labile groups present on a polymer of the photoresist composition. The PAG may be in non-polymeric form or in polymeric form, for example, present in a polymerized repeating unit of the polymer as described above, or as part of a different polymer. In some embodiments, the PAG may be included in the composition as a non-polymerized PAG compound, as a repeating unit of a polymer having a PAG moiety that is derived from a polymerizable PAG monomer, or as a combination thereof.

Suitable non-polymeric PAG compounds may have Formula G⁺A⁻, wherein G⁺ is an organic cation chosen from iodonium cations substituted with two alkyl groups, two aryl groups, or a combination of alkyl and aryl groups; and sulfonium cations substituted with three alkyl groups, three aryl groups, or a combination of alkyl and aryl groups, and A⁻ is a non-polymerizable organic anion. Particularly suitable non-polymeric organic anions include those, the conjugated acids of which have a pKa of from −15 to 1. Particularly preferred anions are fluorinated alkyl sulfonates and fluorinated sulfonimides.

Useful non-polymeric PAG compounds are known in the art of chemically amplified photoresists and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, and di-t-butyphenyliodonium camphorsulfonate. Non-ionic sulfonates and sulfonyl compounds are also known to function as photoacid generators, e.g., nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable non-polymerized photoacid generators are further described in U.S. Pat. No. 8,431,325 to Hashimoto et al. in column 37, lines 11-47 and columns 41-91. Other suitable sulfonate PAGs include sulfonated esters and sulfonyloxy ketones, nitrobenzyl esters, s-triazine derivatives, benzoin tosylate, t-butylphenyl α-(p-toluenesulfonyloxy)acetate, and t-butyl α-(p-toluenesulfonyloxy)acetate; as described in U.S. Pat. Nos. 4,189,323 and 8,431,325.

Typically, when the photoresist composition includes a non-polymeric photoacid generator, it is present in the photoresist composition in an amount of from 0.3 to 65 wt %, more typically 1 to 20 wt %, based on total solids of the photoresist composition.

In some embodiments, G⁺ may be a sulfonium cation of Formula (15) or an iodonium cation of Formula (16):

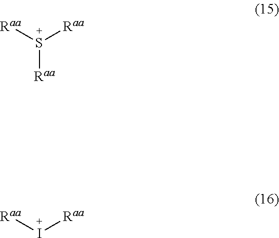

In Formulae (15) and (16), each R^{aa} is independently substituted or unsubstituted C₁₋₂₀ alkyl, substituted or unsubstituted C₃₋₂₀ cycloalkyl, substituted or unsubstituted C₂₋₂₀ alkenyl, substituted or unsubstituted C₆₋₃₀ aryl, substituted or unsubstituted C₃₋₃₀ heteroaryl, substituted or unsubstituted C₇₋₂₀ arylalkyl, or substituted or unsubstituted C₄₋₂₀ heteroarylalkyl. Each R^{aa} may be either separate or connected to another group R^{aa} via a single bond or a divalent linking group to form a ring. Each R^{aa} optionally may include as part of its structure a divalent linking group. Each R^{aa} independently may optionally comprise an acid-labile group chosen, for example, from tertiary alkyl ester groups, secondary or tertiary aryl ester groups, secondary or tertiary ester groups having a combination of alkyl and aryl groups, tertiary alkoxy groups, acetal groups, or ketal groups.

Exemplary sulfonium cations of Formula (15) may include one or more of the following:

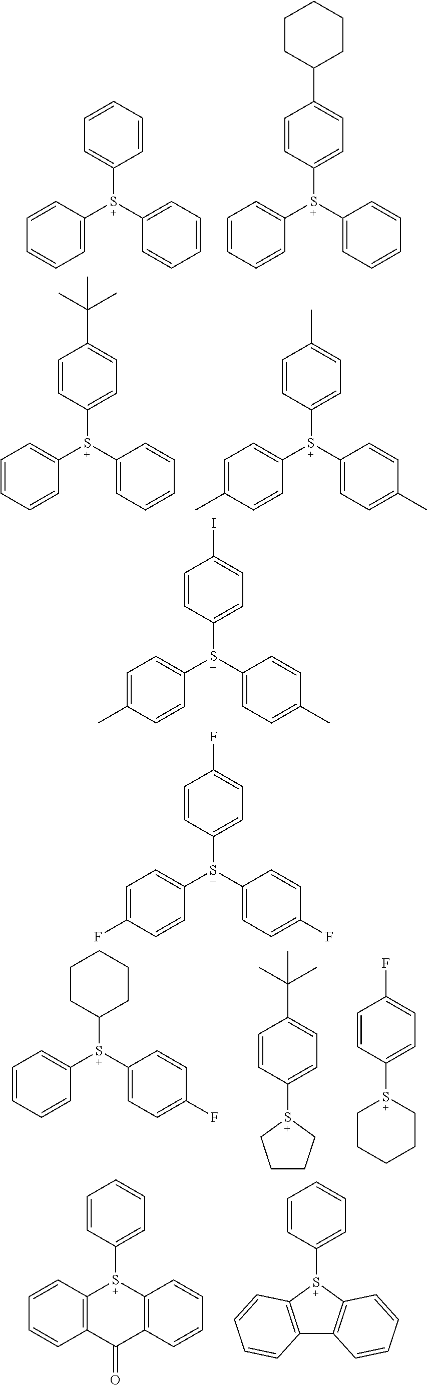

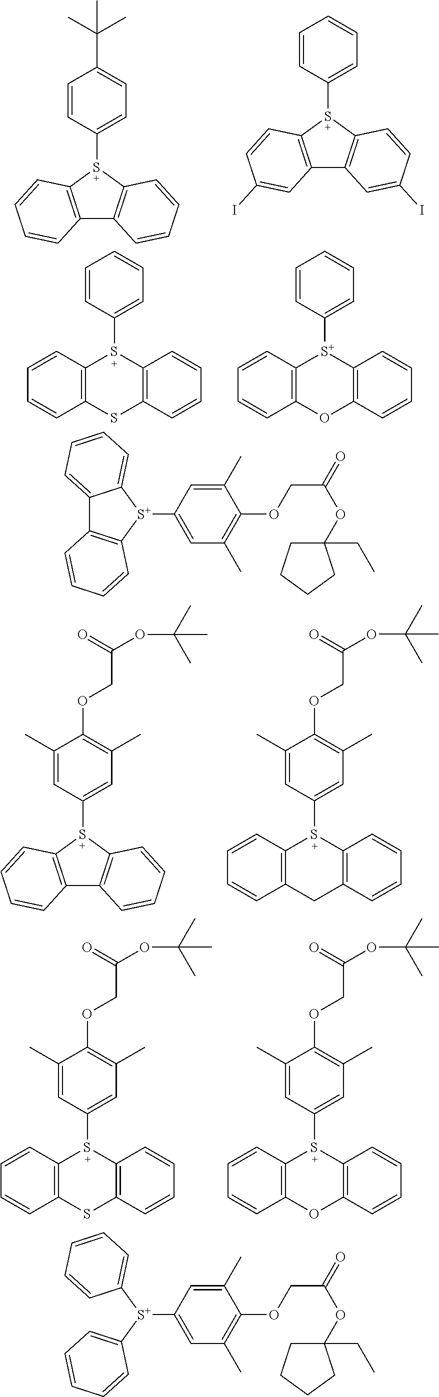

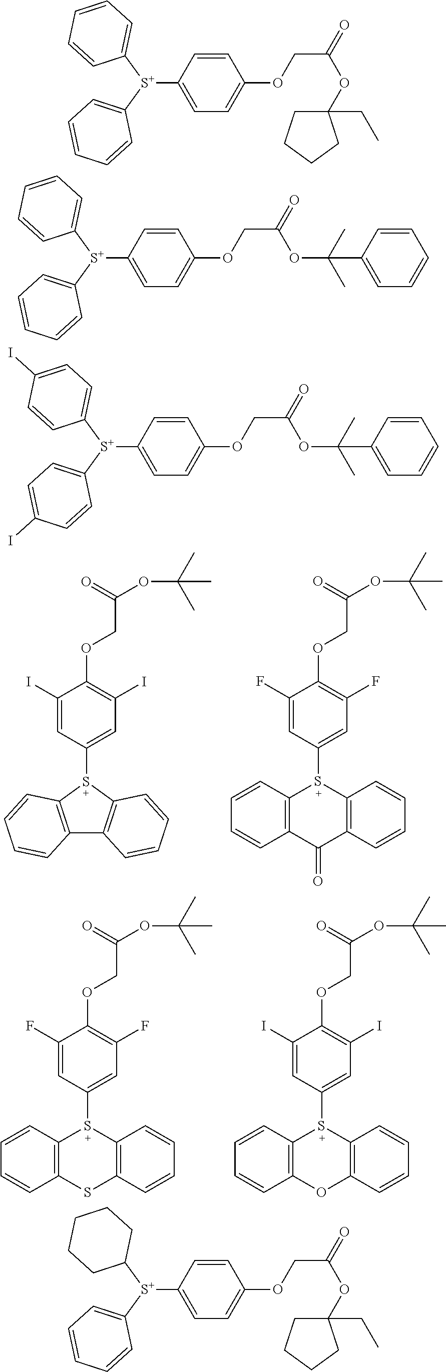

Exemplary iodonium cations of Formula (16) may include one or more of the following:

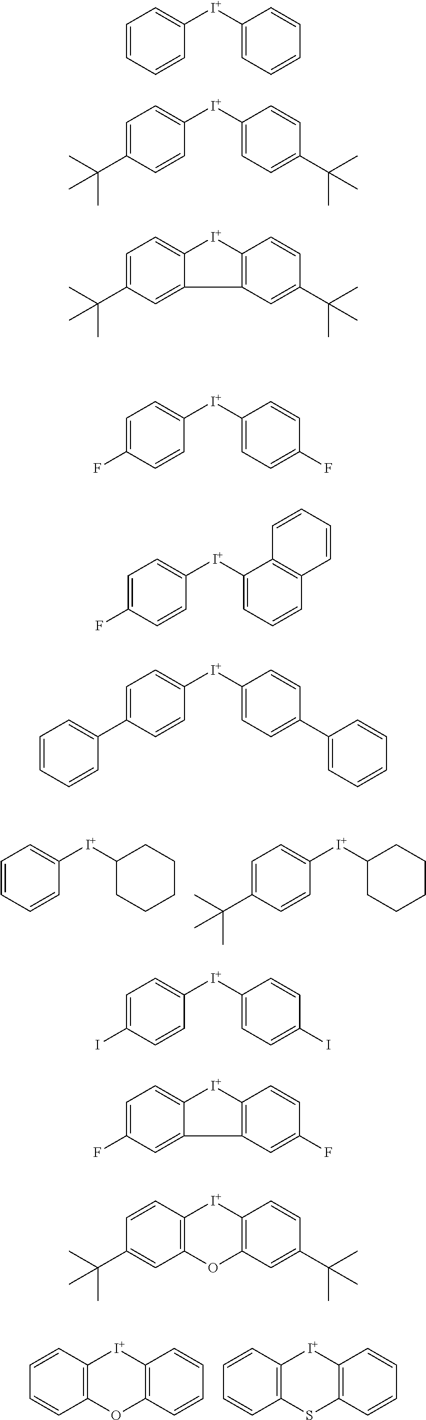

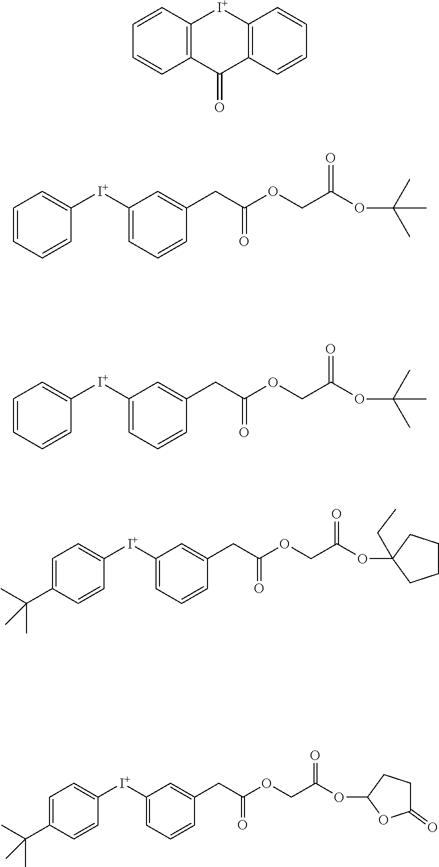

PAGs that are onium salts typically comprise an organic anion having a sulfonate group or a non-sulfonate-type group, such as sulfonamidate, sulfonimidate, methide, or borate.

Exemplary organic anions having a sulfonate group include one or more of the following:

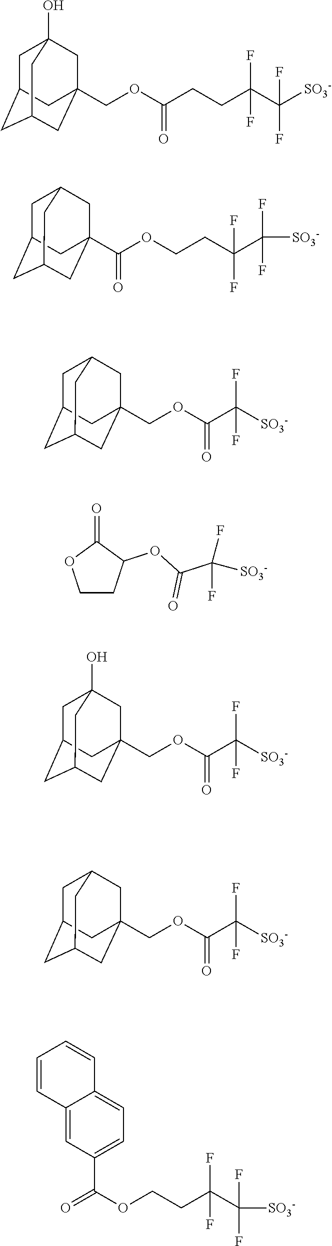

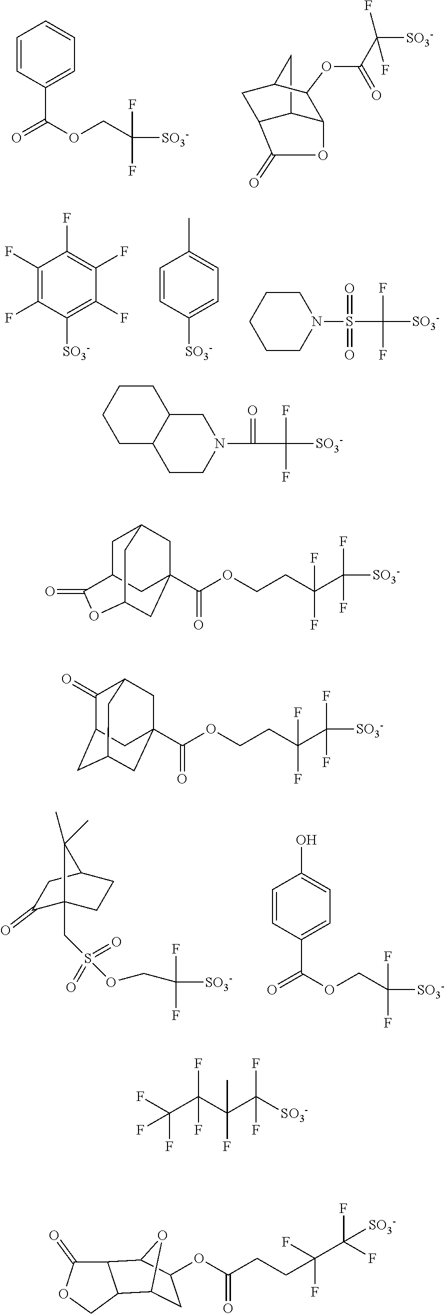

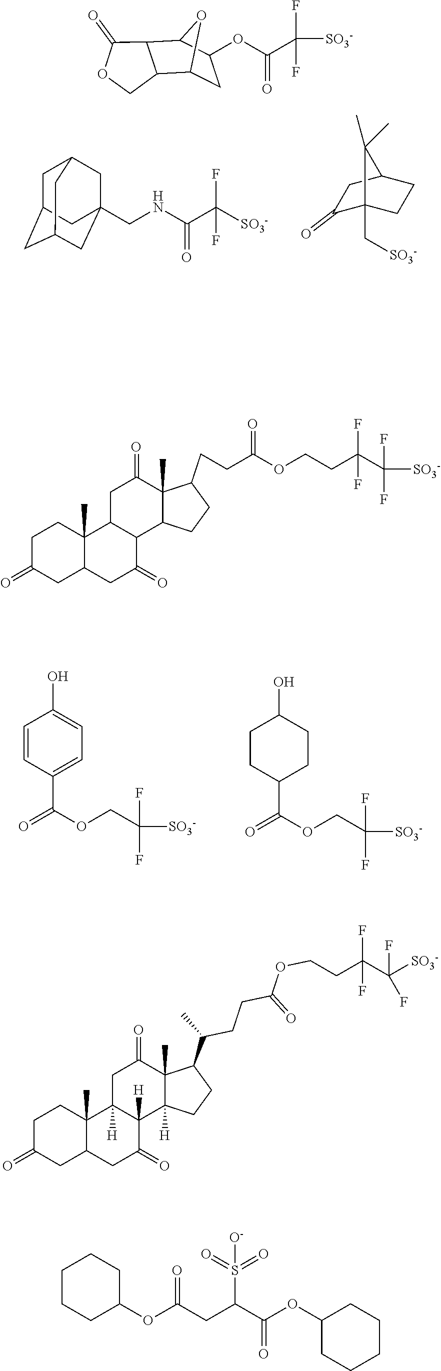

Exemplary non-sulfonated anions include one or more of the following:

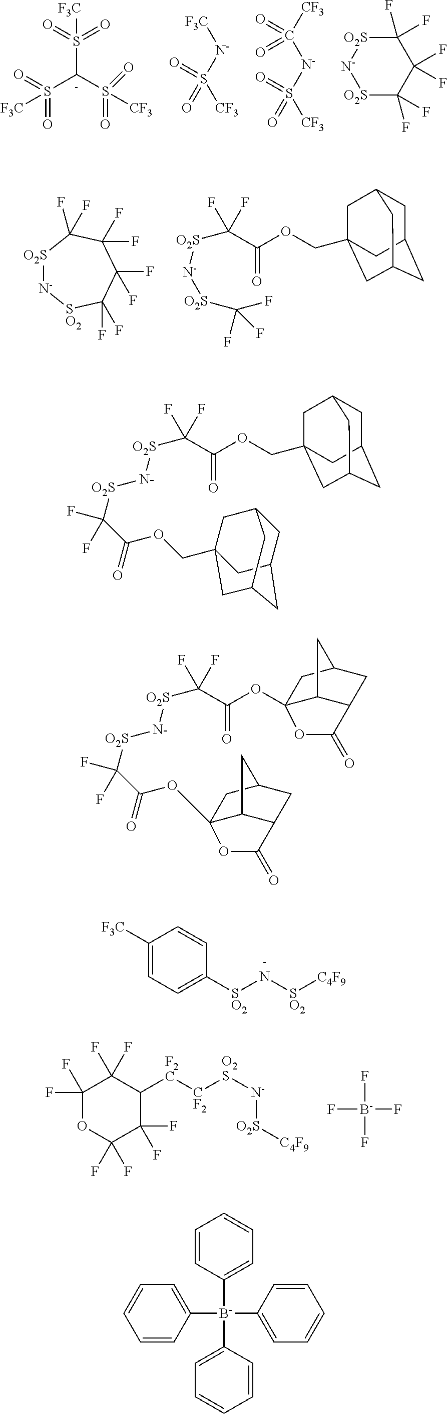

The photoresist composition may optionally comprise a plurality of PAGs. The plurality of PAGs may be polymeric, non-polymeric, or may include both polymeric and non-polymeric PAGs. Preferably, each PAG of the plurality of PAGs is non-polymeric.

In one or more aspects, the photoresist composition may include a first photoacid generator that includes a sulfonate group on the anion, and the photoresist composition may include a second photoacid generator that is non-polymeric, wherein the second photoacid generator may include an anion that is free of sulfonate groups.

In some aspects, the polymer optionally may further include a repeating unit that comprises a PAG-containing moiety, for example a repeating unit derived from one or more monomers of Formula (17):

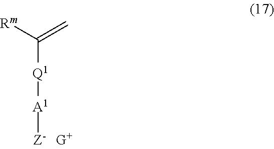

wherein R^{m} may be hydrogen, fluorine, cyano, or substituted or unsubstituted C₁₋₁₀ alkyl. Preferably, R^{m} is hydrogen, fluorine, or substituted or unsubstituted C₁₋₅ alkyl, typically methyl.

In Formula (17), Q¹ may be a single bond or a divalent linking group. Preferably, Q¹ may include 1 to 10 carbon atoms and at least one heteroatom, more preferably —C(O)—O—. A¹ may be one or more of substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, or substituted or unsubstituted C₃₋₃₀ heteroarylene. Preferably, A¹ may be a divalent C₁₋₃₀ perfluoroalkylene group that is optionally substituted. Z⁻ is an anionic moiety, the conjugated acid of which typically has a pKa from −15 to 1. For example, Z⁻ may be a sulfonate, a carboxylate, an anion of a sulfonamide, an anion of a sulfonimide, or a methide anion. Particularly preferred anion moieties are fluorinated alkyl sulfonates and fluorinated sulfonimides. G⁺ is an organic cation as defined above. In some embodiments, G⁺ is an iodonium cation substituted with two alkyl groups, two aryl groups, or a combination of alkyl and aryl groups; or a sulfonium cation substituted with three alkyl groups, three aryl groups, or a combination of alkyl and aryl groups.

Exemplary monomers of Formula (17) may include one or more of the following:

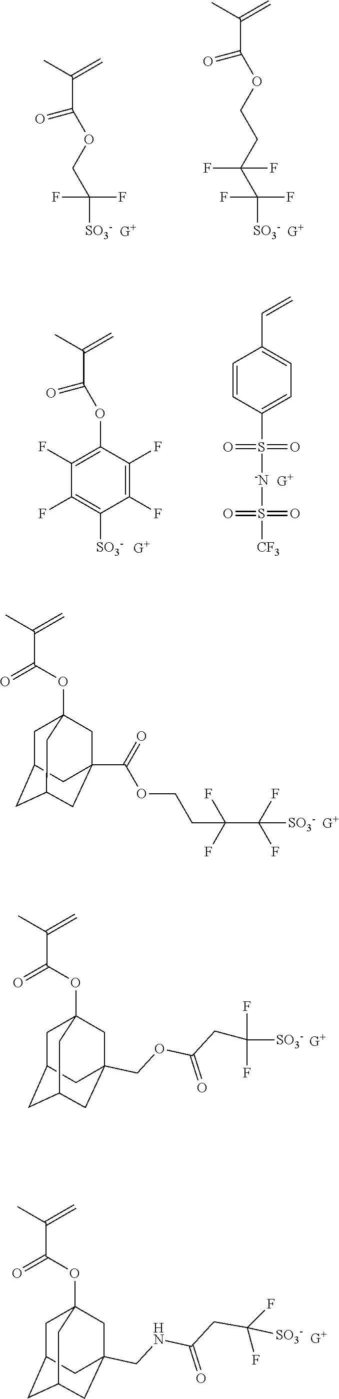

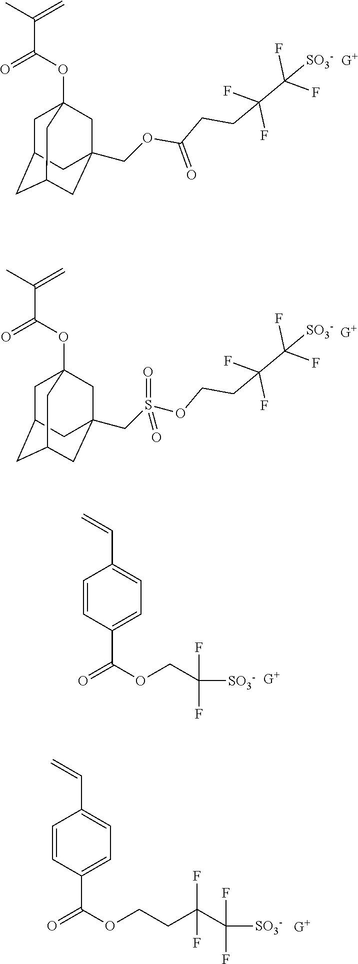

wherein G⁺ is an organic cation as defined herein.

When used, the repeating unit comprising a PAG moiety can be included in a polymer in an amount from 1 to 15 mol %, typically from 1 to 8 mol %, more typically from 2 to 6 mol %, based on total repeating units in the polymer.

The photoresist composition further includes a solvent for dissolving the components of the composition and to facilitate its coating on a substrate. Preferably, the solvent is an organic solvent conventionally used in the manufacture of electronic devices. Suitable solvents include, for example: aliphatic hydrocarbons such as hexane and heptane; aromatic hydrocarbons such as toluene and xylene; halogenated hydrocarbons such as dichloromethane, 1,2-dichloroethane and 1-chlorohexane; alcohols such as methanol, ethanol, 1-propanol, iso-propanol, tert-butanol, 2-methyl-2-butanol, 4-methyl-2-pentanol, and diacetone alcohol (4-hydroxy-4-methyl-2-pentanone); propylene glycol monomethyl ether (PGME); ethers such as diethyl ether, tetrahydrofuran, 1,4-dioxane, and anisole; ketones such as acetone, methyl ethyl ketone, methyl iso-butyl ketone, 2-heptanone, and cyclohexanone (CHO); esters such as ethyl acetate, n-butyl acetate, propylene glycol monomethyl ether acetate (PGMEA), ethyl lactate (EL), hydroxyisobutyrate methyl ester (HBM), and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; water; and combinations thereof. Of these, preferred solvents are PGME, PGMEA, EL, GBL, HBM, CHO, and combinations thereof.

The total solvent content (i.e., cumulative solvent content for all solvents) in the photoresist compositions is typically from 40 to 99 wt %, for example, from 60 to 99 wt %, or from 85 to 99 wt %, based on total solids of the photoresist composition. The desired solvent content will depend, for example, on the desired thickness of the coated photoresist layer and coating conditions.

The polymer is typically present in the photoresist composition in an amount from 0.1 to 99.9 wt %, typically from 0.1 to 20 wt %, and more typically from 1 to 15 wt %, based on total solids of the photoresist composition. It will be understood that “total solids” includes the polymer, PAGs, the additive, and other non-solvent components.

In some aspects, the photoresist composition may further include a second polymer including a repeating unit that includes an acid-labile group, wherein the second polymer is structurally different from the inventive polymer. Such acid-labile groups are as described herein.

For example, the photoresist compositions may include an additional (second) polymer as described above but different in composition, or a polymer that is similar to those described above but does not include each of the requisite repeating units. Additionally, or alternatively, the one or more additional (second) polymers may include those well known in the photoresist art, for example, those chosen from polyacrylates, polyvinylethers, polyesters, polynorbornenes, polyacetals, polyethylene glycols, polyamides, polyacrylamides, polyphenols, novolacs, styrenic polymers, polyvinyl alcohols, or combinations thereof.

The second polymer typically has a M_{w} from 1,000 to 50,000 Da, preferably from 2,000 to 30,000 Da, more preferably 4,000 to 25,000 Da, and still more preferably from 5,000 to 25,000 Da. The PDI of the second polymer is typically from 1.1 to 3, and more typically from 1.1 to 2. Molecular weight values are determined by GPC using polystyrene standards.

The second polymer is typically present in the photoresist composition in an amount from 0.1 to 99.9 wt %, typically from 25 to 90 wt %, and more typically from 45 to 85 wt %, based on total solids of the photoresist composition.

The photoresist composition may further include one or more additional, optional additives. For example, optional additives may include actinic and contrast dyes, anti-striation agents, plasticizers, speed enhancers, sensitizers, photo-decomposable quenchers (PDQ) (and, also known as photo-decomposable bases), basic quenchers, thermal acid generators, surfactants, and the like, or combinations thereof. If present, the optional additives are typically present in the photoresist compositions in an amount of from 0.01 to 10 wt %, based on total solids of the photoresist composition.

PDQs generate a weak acid upon irradiation. The acid generated from a photo-decomposable quencher is not strong enough to react rapidly with acid-labile groups that are present in the resist matrix. Exemplary photo-decomposable quenchers include, for example, photo-decomposable cations, and preferably those also useful for preparing strong acid generator compounds, paired with an anion of a weak acid (pKa>1) such as, for example, an anion of a C₁₋₂₀ carboxylic acid or C₁₋₂₀ sulfonic acid. Exemplary carboxylic acids include formic acid, acetic acid, propionic acid, tartaric acid, succinic acid, cyclohexanecarboxylic acid, benzoic acid, salicylic acid, and the like. Exemplary sulfonic acids include p-toluene sulfonic acid, camphor sulfonic acid and the like. In a preferred embodiment, the photo-decomposable quencher is a photo-decomposable organic zwitterion compound such as diphenyliodonium-2-carboxylate.

The photo-decomposable quencher may be in non-polymeric or polymer-bound form.

When in polymeric form, the photo-decomposable quencher is present in polymerized units on the first polymer or second polymer. The polymerized units containing the photo-decomposable quencher are typically present in an amount from 0.1 to 30 mole %, preferably from 1 to 10 mole % and more preferably from 1 to 2 mole %, based on total repeating units of the polymer.

Exemplary basic quenchers include, for example, linear aliphatic amines such as tributylamine, trioctylamine, triisopropanolamine, tetrakis(2-hydroxypropyl)ethylenediamine:n-tert-butyldiethanolamine, tris(2-acetoxy-ethyl) amine, 2,2′,2″,2′″-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N¹,N¹,N³,N³-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

The basic quenchers may be in non-polymeric or polymer-bound form. When in polymeric form, the quencher may be present in repeating units of the polymer. The repeating units containing the quencher are typically present in an amount of from 0.1 to 30 mole %, preferably from 1 to 10 mole % and more preferably from 1 to 2 mole %, based on total repeating units of the polymer.

Exemplary surfactants include fluorinated and non-fluorinated surfactants and can be ionic or non-ionic, with non-ionic surfactants being preferable. Exemplary fluorinated non-ionic surfactants include perfluoro C₄ surfactants such as FC-4430 and FC-4432 surfactants, available from 3M Corporation; and fluorodiols such as POLYFOX PF-636, PF-6320, PF-656, and PF-6520 fluorosurfactants from Omnova. In an aspect, the photoresist composition further includes a surfactant polymer including a fluorine-containing repeating unit.

Patterning methods using the photoresist compositions of the invention will now be described. Suitable substrates on which the photoresist compositions can be coated include electronic device substrates. A wide variety of electronic device substrates may be used in the present invention, such as: semiconductor wafers; polycrystalline silicon substrates; packaging substrates such as multichip modules; flat panel display substrates; substrates for light emitting diodes (LEDs) including organic light emitting diodes (OLEDs); and the like, with semiconductor wafers being typical. Such substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. Suitable substrates may be in the form of wafers such as those used in the manufacture of integrated circuits, optical sensors, flat panel displays, integrated optical circuits, and LEDs. Such substrates may be any suitable size. Typical wafer substrate diameters are 200 to 300 millimeters (mm), although wafers having smaller and larger diameters may be suitably employed according to the present invention. The substrates may include one or more layers or structures which may optionally include active or operable portions of devices being formed.

Typically, one or more lithographic layers such as a hardmask layer, for example, a spin-on-carbon (SOC), amorphous carbon, or metal hardmask layer, a CVD layer such as a silicon nitride (SiN), a silicon oxide (SiO), or silicon oxynitride (SiON) layer, an organic or inorganic underlayer, or combinations thereof, are provided on an upper surface of the substrate prior to coating a photoresist composition of the present invention. Such layers, together with an overcoated photoresist layer, form a lithographic material stack.

Optionally, a layer of an adhesion promoter may be applied to the substrate surface prior to coating the photoresist compositions. If an adhesion promoter is desired, any suitable adhesion promoter for polymer films may be used, such as silanes, typically organosilanes such as trimethoxyvinylsilane, triethoxyvinylsilane, hexamethyldisilazane, or an aminosilane coupler such as gamma-aminopropyltriethoxysilane. Particularly suitable adhesion promoters include those sold under the AP 3000, AP 8000, and AP 9000S designations, available from DuPont Electronics & Industrial (Marlborough, Massachusetts).

The photoresist composition may be coated on the substrate by any suitable method, including spin coating, spray coating, dip coating, doctor blading, or the like. For example, applying the layer of photoresist may be accomplished by spin coating the photoresist in solvent using a coating track, in which the photoresist is dispensed on a spinning wafer. During dispensing, the wafer is typically spun at a speed of up to 4,000 rotations per minute (rpm), for example, from 200 to 3,000 rpm, for example, 1,000 to 2,500 rpm, for a period from 15 to 120 seconds to obtain a layer of the photoresist composition on the substrate. It will be appreciated by those skilled in the art that the thickness of the coated layer may be adjusted by changing the spin speed and/or the total solids of the composition. A photoresist composition layer formed from the compositions of the invention typically has a dried layer thickness from 3 to 30 micrometers (μm), preferably from greater than 5 to 30 μm, and more preferably from 6 to 25 μm.

The photoresist composition is typically next soft-baked to minimize the solvent content in the layer, thereby forming a tack-free coating and improving adhesion of the layer to the substrate. The soft bake is performed, for example, on a hotplate or in an oven, with a hotplate being typical. The soft bake temperature and time will depend, for example, on the photoresist composition and thickness. The soft bake temperature is typically from 80 to 170° C., and more typically from 90 to 150° C. The soft bake time is typically from 10 seconds to 20 minutes, more typically from 1 minute to 10 minutes, and still more typically from 1 minute to 2 minutes. The heating time can be readily determined by one of ordinary skill in the art based on the ingredients of the composition.

The photoresist layer is next pattern-wise exposed to activating radiation to create a difference in solubility between exposed and unexposed regions. Reference herein to exposing a photoresist composition to radiation that is activating for the composition indicates that the radiation can form a latent image in the photoresist composition. The exposure is typically conducted through a patterned photomask that has optically transparent and optically opaque regions corresponding to regions of the resist layer to be exposed and unexposed, respectively.

Such exposure may, alternatively, be conducted without a photomask in a direct writing method, typically used for e-beam lithography. The activating radiation typically has a wavelength of sub-400 nm, sub-300 nm or sub-200 nm, with 248 nm (KrF), 193 nm (ArF), 13.5 nm (EUV) wavelengths or e-beam lithography being preferred. Preferably, the activating radiation is 248 nm radiation. The methods find use in immersion or dry (non-immersion) lithography techniques. The exposure energy is typically from 1 to 200 millijoules per square centimeter (mJ/cm²), preferably from 10 to 100 mJ/cm² and more preferably from 20 to 50 mJ/cm², dependent upon the exposure tool and components of the photoresist composition.

Following exposure of the photoresist layer, a post-exposure bake (PEB) of the exposed photoresist layer is performed. The PEB can be conducted, for example, on a hotplate or in an oven, with a hotplate being typical. Conditions for the PEB will depend, for example, on the photoresist composition and layer thickness. The PEB is typically conducted at a temperature from 70 to 150° C., preferably from 75 to 120° C., and a time from 30 to 120 seconds. A latent image defined by the polarity-switched (exposed regions) and unswitched regions (unexposed regions) is formed in the photoresist.

The exposed photoresist layer is then developed with a suitable developer to selectively remove those regions of the layer that are soluble in the developer while the remaining insoluble regions form the resulting photoresist pattern relief image. In the case of a positive-tone development (PTD) process, the exposed regions of the photoresist layer are removed during development and unexposed regions remain. Conversely, in a negative-tone development (NTD) process, the exposed regions of the photoresist layer remain, and unexposed regions are removed during development. Application of the developer may be accomplished by any suitable method such as described above with respect to application of the photoresist composition, with spin coating being typical. The development time is for a period effective to remove the soluble regions of the photoresist, with a time of from 5 to 60 seconds being typical. Development is typically conducted at room temperature.

Suitable developers for a PTD process include aqueous base developers, for example, quaternary ammonium hydroxide solutions such as tetramethylammonium hydroxide (TMAH), preferably 0.26 normal (N) TMAH, tetraethylammonium hydroxide, tetrabutylammonium hydroxide, sodium hydroxide, potassium hydroxide, sodium carbonate, potassium carbonate, and the like. Suitable developers for an NTD process are organic solvent-based, meaning the cumulative content of organic solvents in the developer is 50 wt % or more, typically 95 wt % or more, 98 wt % or more, or 100 wt %, based on total weight of the developer. Suitable organic solvents for the NTD developer include, for example, those chosen from ketones, esters, ethers, hydrocarbons, and mixtures thereof. The developer is typically 2-heptanone or n-butyl acetate.

A coated substrate may be formed from the photoresist compositions of the invention. Such a coated substrate includes: (a) a substrate having one or more layers to be patterned on a surface thereof; and (b) a layer of the photoresist composition over the one or more layers to be patterned.

The photoresist pattern may be used, for example, as an etch mask, thereby allowing the pattern to be transferred to one or more sequentially underlying layers by known etching techniques, typically by dry-etching such as reactive ion etching. The photoresist pattern may, for example, be used for pattern transfer to an underlying hardmask layer which, in turn, is used as an etch mask for pattern transfer to one or more layers below the hardmask layer. If the photoresist pattern is not consumed during pattern transfer, it may be removed from the substrate by known techniques, for example, oxygen plasma ashing. The photoresist compositions may, when used in one or more such patterning processes, be used to fabricate semiconductor devices such as memory devices, processor chips (CPUs), graphics chips, optoelectronic chips, LEDs, OLEDs, as well as other electronic devices.

The subject matter is further illustrated by the following non-limiting examples.

### EXAMPLES

### List of Monomers in Synthesis Examples

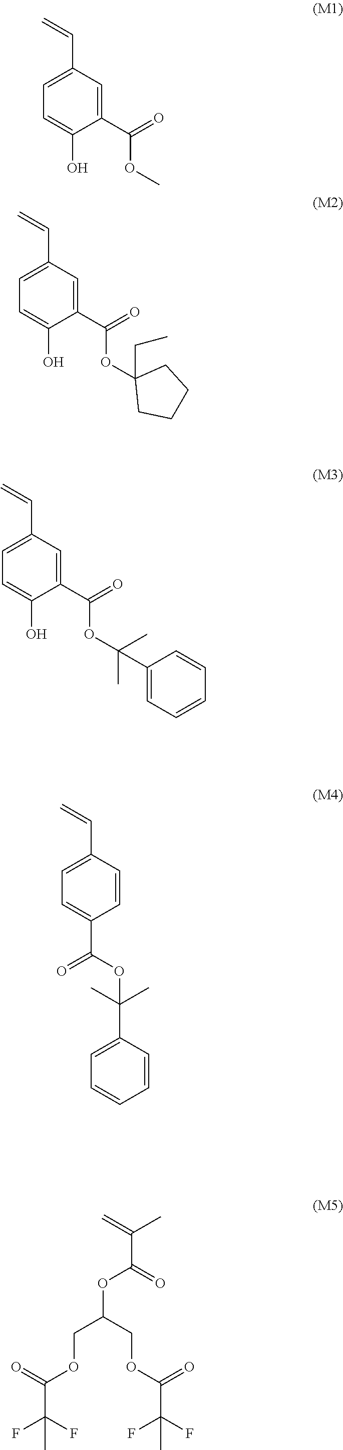 [SMILES: C=Cc1ccc(O)c(C(=O)OC)c1 ; C=Cc1ccc(O)c(C(=O)OC2(CC)CCCC2)c1 ; C=Cc1ccc(O)c(C(=O)OC(C)(C)c2ccccc2)c1 ; C=Cc1ccc(C(=O)OC(C)(C)c2ccccc2)cc1 ; C=C(C)C(=O)OC(COC(=O)C(C)(F)F)COC(=O)C(C)(F)F]

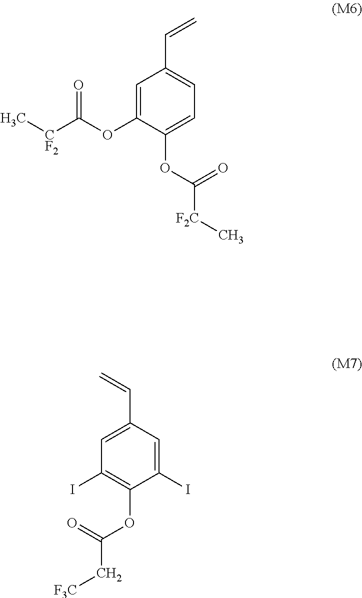 [SMILES: C=Cc1ccc(OC(=O)C(C)(F)F)c(OC(=O)C(C)(F)F)c1 ; C=Cc1cc(I)c(OC(=O)CC(F)(F)F)c(I)c1]

### Synthesis Example 1

The synthetic scheme for the monomer designated M2 is shown in Scheme 1.

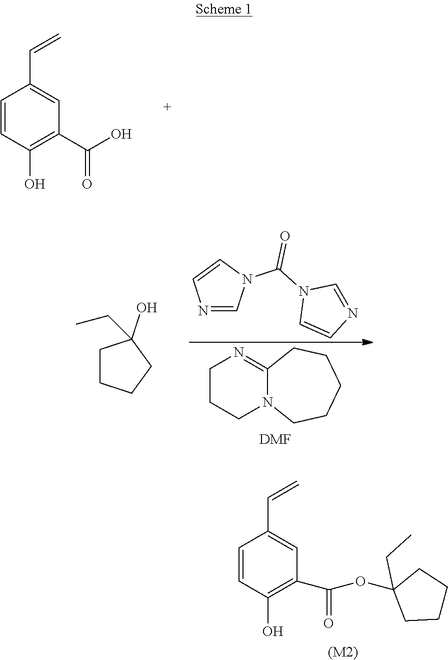

In to 500 milliliters (mL) multi-necked round bottom flask, a condenser, thermal probe and septum were attached. On top of the condenser was connected to the N₂ line. Vinyl salicylic acid (44.0 grams (g)) was added into the flask followed by dimethylformamide (DMF) (200 milliliters (mL)). Then 1,1-carbonyldiimidazole (43.46 g) was added portion wise while stirring under N₂. Once all the bubbles formed in the reaction ceased, the reaction was heated to 55° C. for 1 hour. Then, at 55° C., 1-ethylcyclopentanol (33.67 g) was added into the reaction mixture followed by 1,8-diazabicyclo[5.4.0]undec-7-ene (40.81 g). Then, the reaction was heated at 55° C. for 16 hours under N₂. An aliquot was removed from the reaction and quenched with deionized (DI) water and extracted into heptane. ¹H-NMR analysis was performed to verify that no vinyl salicylic acid was present. Therefore, the reaction was quenched by adding DI water (500 mL). The product was extracted into heptane (3×150 mL). The organic layers were combined and washed with saturated NaCl/water and dried with fluted filter paper. The heptane was removed under reduced pressure. The product was obtained as a pale-yellow solid (46.0 g, yield=66%). ¹H NMR (500 MHz, DMSO-d₆) δ: 7.73 (s, 1H), 7.66 (s, 1H), 6.94 (d, J=8.6 Hz, 1H), 6.69 (s, 1H), 5.65 (s, 1H), 5.16 (s, 1H), 2.21 (s, 2H), 2.05 (s, 2H), 1.73 (s, 6H), 0.86 (td, J=7.4, 2.2 Hz, 3H).

### Synthesis Example 2

The synthetic scheme for the monomer designated M7 is shown in Scheme 2.

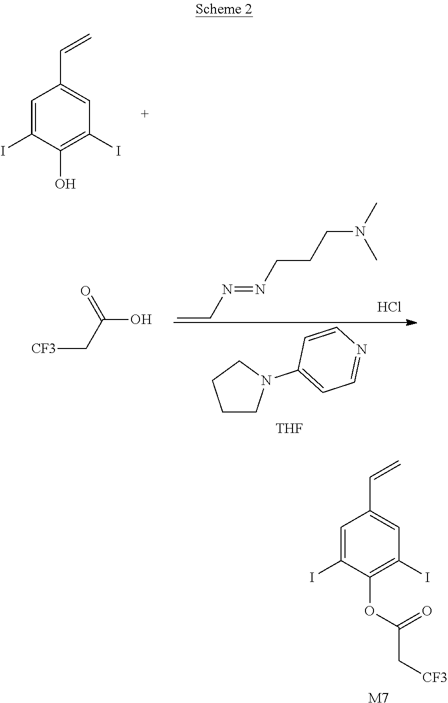

To a 500 mL round bottom flask, 3,5-diiodohydroxystyrene (30.00 g) was added followed by tetrahydrofuran (THF) (200 mL). Ethyldiisopropylaminocarbodiimide hydrochloride (EDC) (24.74 g) was added into the flask with 4-pyrrolidinopyridine (0.60 g) and the reaction was cooled to 0° C. 3,3,3-trifluoropropanoic acid (14.46 g) dissolved in THF (20 mL) was added to the reaction and the temperature of the reaction was increased to room temperature (rt). The reaction was stirred at rt for 4 hours under an N₂ atmosphere. The reaction mixture was cooled to 0° C. and quenched with MilliQ water (500 mL). The reaction mixture was transferred into a separatory funnel and the product was extracted with ethyl acetate (200 mL×3). The organic layer was washed with MilliQ water (300 mL) and dried by passing through a fluted filter paper. The ethyl acetate was then removed under reduced pressure. The resulting product was purified by passing through a silica gel plug with heptane/ethyl acetate (8/2 v/v) to obtain the monomer as a white powder. (33.5 g, yield=86%) ¹H NMR (500 MHz, DMSO-d₆) δ 8.04 (s, 1H), 6.66 (dd, J=17.6, 11.0 Hz, 1H), 5.98 (d, J=17.6 Hz, 1H), 5.37 (d, J=11.0 Hz, 1H), 4.18 (q, J=10.6 Hz, 1H). ¹⁹F NMR (470 MHz, DMSO) δ-61.63.

### Synthesis Example 3

The synthetic scheme for the polymer designated AP-6 is shown in Scheme 3.

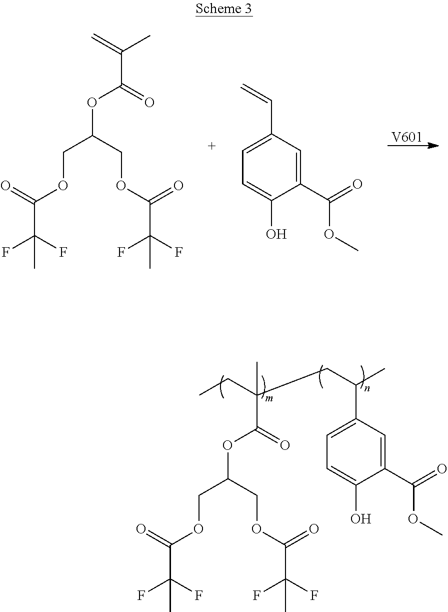

A reactor was charged with 10.0 g PGMEA and purged with N₂ for 30 minutes while heating to 85° C. A monomer and initiator solution was prepared by dissolving M5 (14.13 g), M1 (0.89 g), and azo initiator dimethyl 2,2′-azobis(2-methylpropionate) (obtained as V-601 from Wako Pure Chemical Industries, Ltd.) (1.15 g) in PGMEA (18.00 g), and this was loaded into a syringe. The syringe was covered with ice pack to keep the solution temperature below room temperature. After the reactor temperature was stabilized at 85° C., the monomer and initiator solution were fed into the reactor over 3 hours. After complete addition, the reactor was held at 85° C. for another 3 hours, and then cooled to 25° C. The product was precipitated into methanol and decanted. The resulting precipitate (11.0 g) was washed with methanol and dissolved in PGMEA (51.0 g). The PGMEA was removed under reduced pressure to provide a final polymer solution of 49.4 g with solid polymer content of 18.8 wt %. Mw=11.4 kDa, Mn=8.07 kDa, PDI=1.47, Composition=M5/M1 (mol %): 89.1%/10.9%.

### Synthesis Example 4

The polymer designated AP-5 was prepared as shown in Scheme 4.

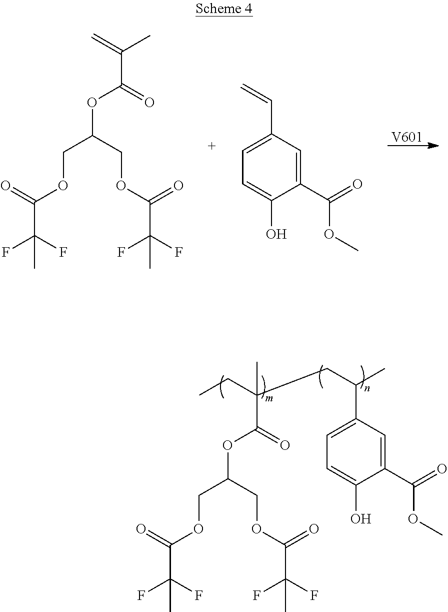

A reactor was charged with 7.34 g PGMEA and purged with N₂ for 30 minutes while heating to 85° C. A monomer and initiator solution was prepared by dissolving M5 (12.74 g), M1 (1.26 g), and initiator V601 (0.74 g) in PGMEA (15.86 g), and this was loaded it to a syringe.

The syringe was covered with ice pack to keep the solution temperature below room temperature. After the reactor temperature was stabilized at 85° C., the monomer and initiator solution were fed into the reactor over 3 hours. After complete addition, the reactor was held at 85° C. for another 3 hours, and then cooled to 25° C. to give 36.7 g of a polymer solution at 40.0 wt % solid content. This polymer solution was diluted with PGMEA (36.7 g) to obtain 20.0 wt % solid polymer in PGMEA solution. Mw=10.0 kDa, Mn=4.72 kDa, PDI=2.12, Composition=M5/M1 (mol %): 86.5%/13.5%.

### Synthesis Example 5

The polymer designated AP-3 was prepared as shown in Scheme 5.

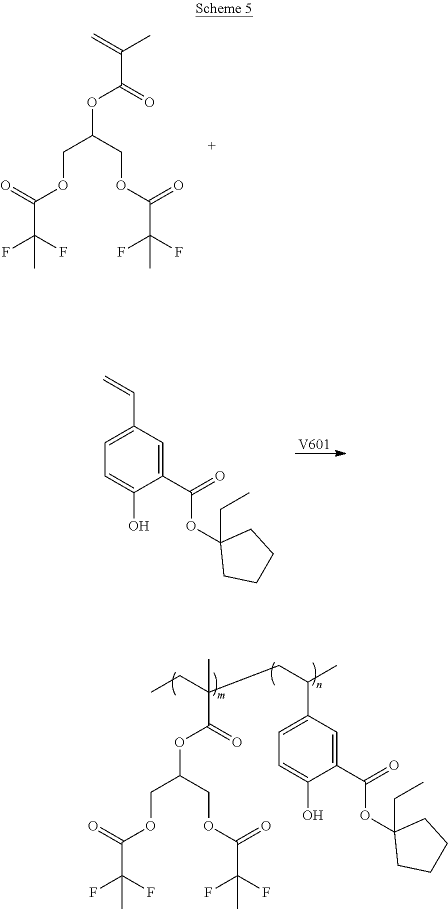

A reactor was charged with 7.37 g of PGMEA and purged with N₂ for 30 minutes while heating to 85° C. A monomer and initiator solution was prepared by dissolving M5 (13.16 g), M2 (0.84 g), and initiator V601 (0.74 g) in PGMEA (15.92 g), and this was loaded into a syringe.

The syringe was covered with an ice pack to keep the solution temperature below room temperature. After the reactor temperature was stabilized at 85° C., the monomer and initiator solution was fed into the reactor over 3 hours. After complete addition, the reactor was held at 85° C. for another 3 hours, and then cooled to 25° C. to give 36.8 g of a polymer solution at 40.0 wt % solid content. This polymer solution was diluted with PGMEA (36.8 g) to obtain a 20.0 wt % solid polymer in PGMEA solution. Mw=10.2 kDa, Mn=4.73 kDa, PDI=2.16, Composition=M5/M2 (mol %): 93.6%/6.4%.

### Synthesis Example 6

The polymer designated AP-4 was prepared as shown in Scheme 6.

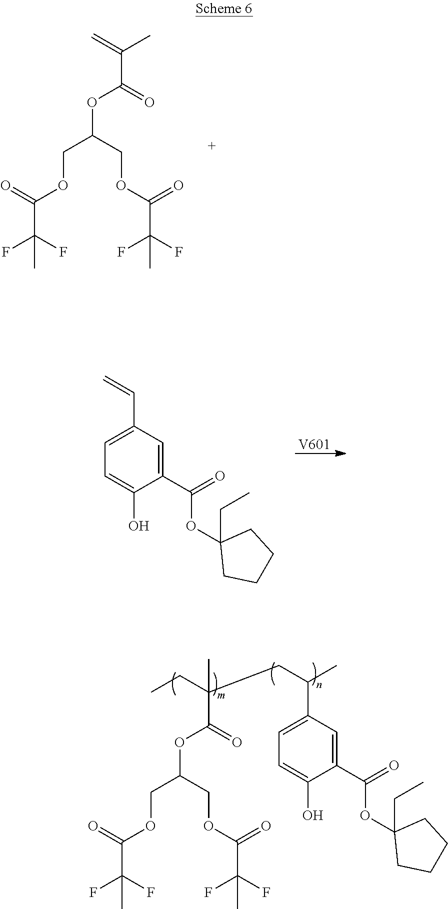

A reactor was charged with 7.39 g of PGMEA and purged with N₂ for 30 minutes while heating to 85° C. A monomer and initiator solution was prepared by dissolving M5 (12.24 g), M2 (1.76 g), and initiator V601 (0.77 g) in PGMEA (15.95 g), and this was loaded into a syringe.

The syringe was covered with an ice pack to keep the solution temperature below room temperature. After the reactor temperature was stabilized at 85° C., the monomer and initiator solution was fed into the reactor over 3 hours. After complete addition, the reactor was held at 85° C. for another 3 hours, and then cooled to 25° C. to give 36.9 g of a polymer solution at 40.0 wt % solid content. This polymer solution was diluted with PGMEA (36.9 g) to obtain a 20.0 wt % solid polymer in PGMEA solution. Mw=9.51 kDa, Mn=4.68 kDa, PDI=2.03, Composition=M5/M2 (mol %): 86.7%/13.3%.

### Synthesis Example 7

The polymer designated AP-1 was prepared as shown in Scheme 7.

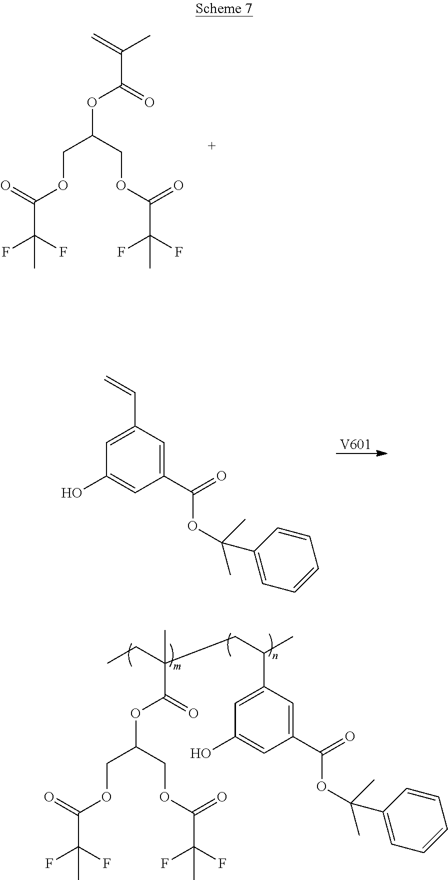

A reactor was charged with 7.37 g of PGMEA and purged with N₂ for 30 minutes while heating to 85° C. A monomer and initiator solution was prepared by dissolving M5 (13.09 g), M3 (0.91 g), and initiator V601 (0.73 g) in PGMEA (15.86 g), and this was then loaded into to a syringe. The syringe was covered with an ice pack to keep the solution temperature below room temperature. After the reactor temperature was stabilized at 85° C., the monomer and initiator solution was fed into the reactor over 3 hours. After complete addition, the reactor was held at 85° C. for another 3 hours, and then cooled to 25° C. to give 36.8 g of a polymer solution at 40.0 wt % solid content. This polymer solution was diluted with PGMEA (36.8 g) to obtain a 20.0 wt % solid polymer in PGMEA solution. Mw=10.2 kDa, Mn=5.24 kDa, PDI=1.95, Composition=M5/M3 (mol %): 92.4%/7.6%.

### Synthesis Example 8

The polymer designated AP-2 was prepared as shown in Scheme 8.

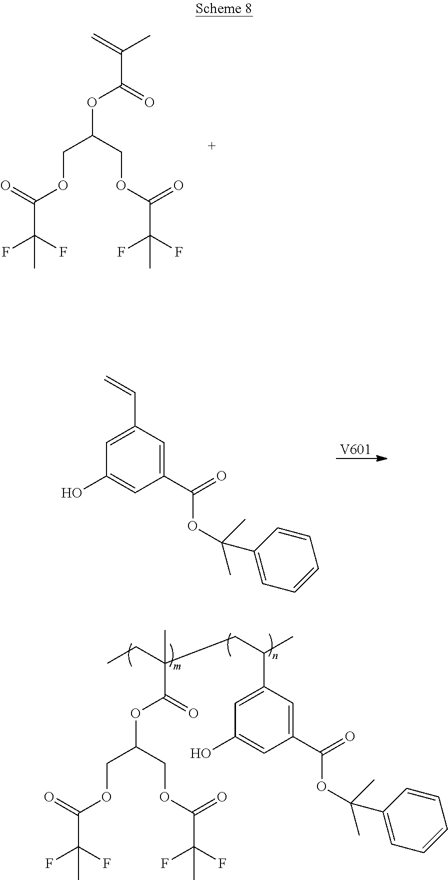

A reactor was charged with 7.35 g of PGMEA and purged with N₂ for 30 minutes while heating to 85° C. A monomer and initiator solution was prepared by dissolving M5 (12.11 g), M3 (1.89 g), and initiator V601 (0.71 g) in PGMEA (15.89 g), and this was loaded into a syringe. The syringe was covered with an ice pack to keep the solution temperature below room temperature. After the reactor temperature was stabilized at 85° C., the monomer and initiator solution was fed into the reactor over 3 hours. After complete addition, the reactor was held at 85° C. for another 3 hours, and then cooled to 25° C. to give 36.7 g of a polymer solution at 40.0 wt % solid content. This polymer solution was diluted with PGMEA (36.7 g) to obtain 20.0 wt % solid polymer in PGMEA solution. Mw=10.2 kDa, Mn=5.00 kDa, PDI=2.03, Composition=M5/M3 (mol %): 84.5%/15.5%.

### Synthesis Example 9

The polymer designated AP-7 was prepared using a similar procedure as in Synthesis Examples 3 to 8, except the monomers were M6 and M2. Mw=8.14 kDa, Mn=4.26 kDa, PDI=1.91, Composition=M6/M2 (mol %): 91.5%/8.5%.

### Synthesis Example 10

The polymer designated AP-8 was prepared using a similar procedure as in Synthesis Examples 3 to 8, except the monomers were M6 and ML. Mw=9.66 kDa, Mn=5.12 kDa, PDI=1.89, Composition=M6/M1 (mol %): 91.8%/8.2%.

### Synthesis Example 11

The polymer designated AP-9 was prepared using a similar procedure as in Synthesis Examples 3 to 8, except the monomers were M6 and M3. Mw=12.37 kDa, Mn=5.75 kDa, PDI=2.15, Composition=M6/M3 (mol %): 87.2%/12.8%.

### Synthesis Example 12

The polymer designated AP-10 was prepared using a similar procedure as in Synthesis Examples 3 to 8, except the monomers were M6 and M2. Mw=9.70 kDa, Mn=5.01 kDa, PDI=1.94, Composition=M6/M2 (mol %): 80.2%/19.8%.

### Synthesis Example 13

The polymer designated AP-11 was prepared using a similar procedure as in Synthesis Examples 3 to 8, except the monomers were M6, M7, and M2. Mw=10.6 kDa, Mn=5.52 kDa, PDI=1.93, Composition=M6/M7/M2 (mol %): 79.9%/11.8%/8.3%.

### Synthesis Example 14

The comparative polymer designated AP-12 was prepared as shown in Scheme 9.

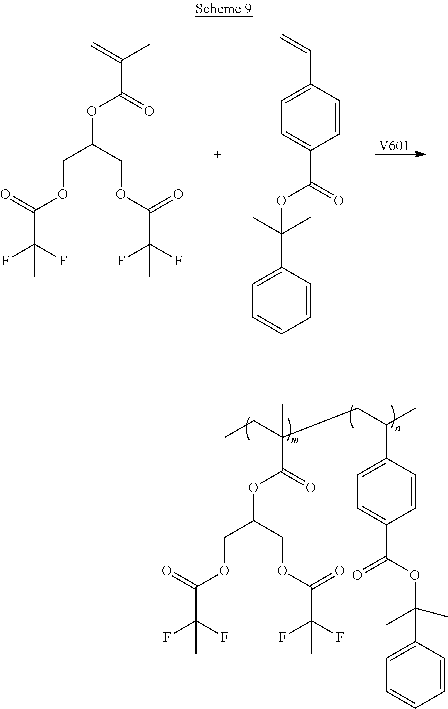

A reactor was charged with 12.50 g of PGMEA and purged with N₂ for 30 minutes while heating to 85° C. A monomer and initiator solution was prepared by dissolving M5 (27.44 g), M4 (2.57 g), and initiator V601 (1.70 g) in PGMEA (32.5 g), and this was loaded into a syringe. The syringe was covered with an ice pack to keep the solution temperature below room temperature. After the reactor temperature was stabilized at 85° C., the monomer and initiator solution was fed into the reactor over 3 hours. After complete addition, the reactor was held at 85° C. for another 3 hours, and then cooled to 25° C. The product was precipitated into methanol, collected, was washed twice with methanol while stirring. The product was dried under high vacuum for 48 hours to obtain the polymer (20.0 g). The polymer was dissolved in PGMEA to obtain a 20 wt % solution. Mw=13.1 kDa, Mn=9.1 kDa, PDI=1.30, Composition=M5/M4 (mol %): 89.5%/10.5%.

### Dissolution Rate (DR) Evaluation

On a TEL ACT-8 wafer track, 8-inch silicon wafers were primed with HMDS at 120° C. for 30 seconds, coated with a 5 wt % solution of the polymer in PGMEA and soft baked at 110° C. for 60 seconds to give a film layer having a thickness of about 100-120 nm. The initial film thickness was measured and shown in Table 1. The wafers were then treated with MF™ CD26 tetramethylammonium hydroxide (TMAH) developer (DuPont Electronics & Industrial) for 60 seconds, rinsed with DI water, and dried. The film thickness after developer treatment of measured and shown in Table 1. The dissolution rate of the polymer is determined by Equation 1, where the change in film thickness (ΔFT) is determined according to Equation 2 as the film thickness (FT) before development minus the FT after development. The dissolution rate (DR) is reported in angstroms per second (Å/s).

$$Dissolution rate ( DR ) = Δ FT / Development time ( s ) \qquad Equation 1$$

$$Δ FT = FT Before Dev - FT After Dev \qquad Equation 2$$

TABLE 1

| | FT | FT | | |
|---|---|---|---|---|
| | Before | After | | |
| | Dev | Dev | Δ FT | DR |
| Polymer | (Å) | (Å) | (Å) | (Å/s) |
| AP-1 | 1125.5 | 269.0 | 856.6 | 14.3 |
| AP-2 | 1170.0 | 798.9 | 371.1 | 6.2 |
| AP-3 | 1188.8 | 81.6 | 1107.2 | 18.5 |
| AP-4 | 1221.3 | 731.8 | 489.5 | 8.2 |
| AP-5 | 1185.1 | 242.4 | 942.8 | 15.7 |
| AP-6 | 1276.5 | 387.4 | 889.2 | 14.8 |
| AP-7 | 1387.7 | 22.6 | 1365.1 | 22.8 |
| AP-8 | 1221.2 | 23.0 | 1198.2 | 20.0 |
| AP- 9 | 1255.8 | 5.1 | 1250.8 | 20.8 |
| AP-10 | 1203.8 | 6.6 | 1197.2 | 20.0 |
| AP- 11 | 1193.5 | 255.7 | 937.8 | 15.6 |
| Comparative AP-12 | 1234.8 | 894.2 | 340.6 | 5.7 |

As shown in Table 1, the inventive polymers AP-1 to AP-6 and AP-7 to AP-11 achieved improved (higher) developer dissolution rates than comparative polymer AP 12, which provided the desired base solubility to the polymer.

### Contact Angle Evaluation

On a TEL ACT-8 wafer track, 8-inch silicon wafers were primed with HMDS at 120° C. for 30 seconds, coated with a 5 wt % solution of the polymer in PGMEA and soft baked at 110° C. for 60 seconds to give a film layer having a thickness of about 100-120 nm. The contact angle for each of the polymer solutions was measured on a Kruss contact angle goniometer using deionized Millipore filtered water. Receding angle as coated with soft bake was then measured at the beginning of lateral drop motion before rapid acceleration. Receding angle after develop/DI water rinse was measured with wafers treated with MF™ CD26 TMAH developer (DuPont Electronics & Industrial) for 60 seconds, rinsed with DI water, and dried. The results of contact angles of samples before and after being exposure to developer are shown in Table 2 and Table 3. In Tables 2 and 3, comparative example AP-12 was tested on separate days, once with the polymers AP-1 to AP-6 as shown in Table 2, and once with the polymer AP-7 to AP-11 as shown in Table 3.

TABLE 2

| | Receding | Receding |
|---|---|---|
| | Angle as | Angle after |
| | coated with | develop/DI |
| | soft bake | water rinse |
| Polymer | (°) | (°) |
| AP-1 | 63.85 | <25.42 |
| AP-2 | 66.17 | 16.06 |
| AP-3 | 52.19 | <17.46 |
| AP-4 | 66.70 | <29.46 |
| AP-5 | 62.03 | <25.72 |
| AP-6 | 67.64 | 14.43 |
| Comparative AP-12 | 74.20 | 14.82 |

TABLE 3

| | Receding | Receding |
|---|---|---|
| | Angle as | Angle after |
| | coated with | develop/DI |
| | soft bake | water rinse |
| Polymer | (°) | (°) |
| AP-7 | >89 | 37.72 |
| AP-8 | >89 | 39.06 |
| AP-9 | 82.38 | 37.42 |
| AP-10 | 84.47 | 30.09 |
| AP-11 | 83.43 | 24.36 |
| Comparative AP-12 | 70.34 | 12.35 |

As shown in Table 2, the polymers AP-1 to AP-6 achieved lower receding angle (contact angle as coated with soft bake) than comparative polymer AP 12. After development, all samples showed reduced receding angle compared to before developer treatment.

As shown in Table 3, the inventive polymers AP-7 to AP-11 achieved higher receding angle (contact angle as coated with soft bake) than comparative polymer AP-12. After development, all samples showed reduced receding angle compared to before developer treatment.

### Photoresist Compositions and Evaluation

Photoresist compositions were prepared by dissolving solid components in solvents using the materials and amounts indicated in Table 4, where the amounts are expressed in wt % based on 100 wt % of total weight of the solids. The total solids content for the photoresist compositions was 2.2 wt %. The solvent system contained PGMEA (50 wt %) and methyl-2-hydroxyisobutyrate (50 wt %). Each mixture was shaken using a mechanical shaker and then filtered through a PTFE disk-shaped filter having a pore size of 0.2 micron.

Lithography was performed using a CLEAN TRAC ACT8 (TEL, Tokyo Electron Co.) wafer track. 200 nm wafers for photolithographic testing were coated with an AR™ 3 BARC (DuPont Electronics & Industrial) and softbaked at 205° C. for 60 seconds to give a 70 nm film. A coating of AR™ 40A BARC (DuPont Electronics & Industrial) was then disposed on the AR™ 3 layer and softbaked at 215° C. for 60 seconds to form a second BARC layer having a thickness of about 80 nm. A photoresist composition was then coated onto the dual BARC stack and soft-baked at 110° C. for 60 seconds to give a photoresist film layer having a thickness of about 70 nm.

The wafers were exposed with 248 nm radiation on a CANON FPA-5000 ES4 scanner (NA=0.8, outer sigma=0.85, inner sigma=0.57) with a mask having the features of choice. The wafers were post-exposure baked at 90° C. for 60 seconds, developed with MF™ CD26 TMAH developer (DuPont Electronics & Industrial) for 60 seconds, rinsed with DI water, and dried. Critical dimension (CD) linewidth measurements of the formed patterns were made using a HITACHI S-9380 CD-SEM. LWR values were determined by top-down SEM at an accelerating voltage of 800 volts (V), probe current of 8.0 picoamperes (pA), using 200 Kx magnification at 1.0 digital zoom, with the number of frames set to 64. The LWR was measured over a 2 μm line length in steps of 40 nm and reported as the average LWR for the measured region. Sizing energy (E_{size}) and line width roughness (LWR) of the lines were determined based on the CD measurements. The pseudo Z-factor is reported below and was determined according to Equation 3:

$$Pseudo Z - factor = ( {E}_{s i z e} ) \times {( LWR )}^{2} \qquad Equation 3$$

where E_{size} is reported in millijoules per square centimeter (mJ/cm²), LWR is reported in nanometers (nm), and the pseudo Z-factor is reported in mJ×10⁻¹¹. The pseudo Z-factor (Z′-factor) is a modified measure of photoresist performance based on the Z-factor, which is a known parameter indicative of RLS (Resolution, Line Edge Roughness, Sensitivity) photoresist performance (see, e.g., Wallow, T. et al Proc. SPIE 6921, 69211F, 2008). The pseudo Z-factor is calculated at a constant resolution (CD size).

Structure of polymer P1, PAG-1, and quencher Q1:

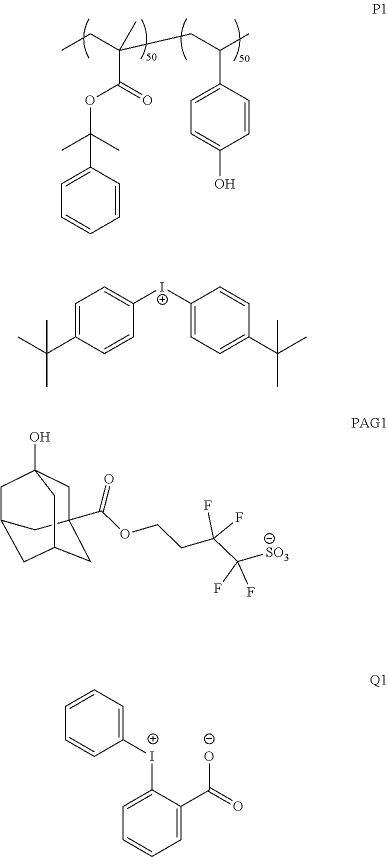

TABLE 4

| | Photoresist | | | Additive | E_{size} | LWR | Z′- |
|---|---|---|---|---|---|---|---|
| Sample | Polymer | PAG | Quencher | Polymer | (mJ/cm²) | (nm) | factor |
| PR-1 | P1 | PAG-1 | Q1 | AP-1 | 109.79 | 6.67 | 4882 |
| | [71.3] | [17.8] | [3.9] | [7.0] | | | |
| PR-2 | P1 | PAG-1 | Q1 | AP-2 | 112.37 | 6.37 | 4561 |
| | [71.3] | [17.8] | [3.9] | [7.0] | | | |
| PR-3 | P1 | PAG-1 | Q1 | AP-3 | 113.28 | 6.55 | 4866 |
| | [71.3] | [17.8] | [3.9] | [7.0] | | | |
| PR-4 | P1 | PAG-1 | Q1 | AP-4 | 113.45 | 6.26 | 4443 |
| | [71.3] | [17.8] | [3.9] | [7.0] | | | |
| PR-5 | P1 | PAG-1 | Q1 | AP-5 | 112.49 | 6.40 | 4605 |
| | [71.3] | [17.8] | [3.9] | [7.0] | | | |
| PR-6 | P1 | PAG-1 | Q1 | AP-6 | 111.13 | 6.46 | 4634 |
| | [71.3] | [17.8] | [3.9] | [7.0] | | | |
| PR-7 | P1 | PAG-1 | Q1 | AP-7 | 109.95 | 6.98 | 5362 |
| | [71.3] | [17.8] | [3.9] | [7.0] | | | |
| PR-8 | P1 | PAG-1 | Q1 | AP-8 | 110.90 | 7.35 | 5984 |
| | [71.3] | [17.8] | [3.9] | [7.0] | | | |
| PR-9 | P1 | PAG-1 | Q1 | AP-9 | 110.53 | 6.89 | 5249 |
| | [71.3] | [17.8] | [3.9] | [7.0] | | | |
| PR-10 | P1 | PAG-1 | Q1 | AP-10 | 111.70 | 6.27 | 4393 |
| | [71.3] | [17.8] | [3.9] | [7.0] | | | |
| Comparative | P1 | PAG-1 | Q1 | AP-12[7.0] | 112.05 | 6.72 | 5060 |
| PR-11 | [71.3] | [17.8] | [3.9] | | | | |

As can be seen in Table 4, the photoresist compositions PR-1 to PR-6 achieved improved LWR (a decreased LWR value) and pseudo-Z factors (a decreased pseudo-Z factor value) relative to comparative photoresist composition PR-11 in L/S patterning under KrF exposure. The photoresist compositions PR-7 to PR-10 achieved faster photospeed (a decreased E_{size} value) relative to comparative photoresist composition PR-11 in L/S patterning under KrF exposure.

1. A polymer comprising:
a first repeating unit derived from a polymerizable compound comprising an aromatic group, wherein the aromatic group is substituted with:
a first substituent group comprising an ethylenically unsaturated double bond;
a second substituent group that is a hydroxyl group; and
a third substituent group comprising a carbonyl group,
wherein the first substituent group, the second substituent group, and the carbonyl group of the third substituent group are each bonded to a different carbon atom of the aromatic group; and
a second repeating unit comprising a base-labile group, wherein the first repeating unit and the second repeating unit are structurally different.

2. The polymer of claim 1, wherein the first repeating unit is derived from a polymerizable compound of Formula (1): 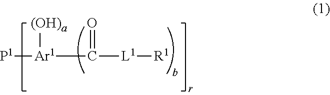
wherein,
P¹ comprises a group comprising an ethylenically unsaturated double bond, wherein P¹ optionally forms a ring with Ar¹,
Ar¹ is substituted or unsubstituted C₆₋₆₀ aryl or substituted or unsubstituted C₃₋₆₀ heteroaryl;
each L¹ is independently a single bond or a divalent linking group;
each R¹ is independently a substituted or unsubstituted C₁₋₃₀ alkyl, substituted or unsubstituted C₃₋₃₀ cycloalkyl, substituted or unsubstituted C₁₋₃₀ heteroalkyl, substituted or unsubstituted C₂₋₃₀ heterocycloalkyl, substituted or unsubstituted C₆₋₆₀ aryl, or substituted or unsubstituted C₃₋₆₀ heteroaryl;
each a is an integer of 1 or greater,
each b is an integer of 1 or greater,
provided a+b is an integer of 10 or less; and
r is an integer of 1 or greater.

3. The polymer of claim 2, wherein the moiety —C(O)-L¹-R¹ comprises an acid labile group.

4. The polymer of claim 1, wherein the base-labile group comprises a fluorinated alkyl ester group, a fluorinated aryl ester group, or a hexafluoroalcohol group.

5. The polymer of claim 1, wherein the second repeating unit is derived from one or more polymerizable compounds that each comprise:
a polymerizable group comprising an ethylenically unsaturated double bond; and
a base-labile group comprising a structure represented by Formula (4), 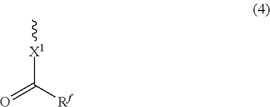
wherein,
X¹ is O, S, or —N(R^{c})—, wherein R^{c} is hydrogen or C₁₋₆ alkyl; and
R^{f} is a substituted or unsubstituted fluoroalkyl group comprising a fluorine atom or a fluoroalkyl group bonded to a carbon atom at an alpha position with respect to the carbonyl group.

6. The polymer of claim 1, wherein the second repeating unit is derived from one or more polymerizable compounds of Formula (5): 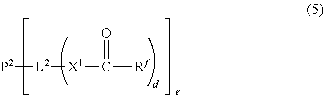
wherein, in Formula (5),
P² is a group comprising an ethylenically unsaturated double bond, wherein P² optionally forms a ring with L²,
L² is a single bond or a linking group;
each X¹ is independently O, S, or —N(R^{c})—, wherein R^{c} is hydrogen or C₁₋₆ alkyl;
each R^{f} independently is a substituted or unsubstituted fluoroalkyl group comprising a fluorine atom or a fluoroalkyl group bonded to a carbon atom at an alpha position with respect to the carbonyl group;
each d is an integer of 1 or greater; and
e is an integer of 1 or greater.

7. The polymer of claim 6, wherein L² comprises an aromatic group substituted with at least one halogen.

8. A photoresist composition, comprising:
the polymer of claim 1;
a photoacid generator; and
a solvent.

9. The photoresist composition of claim 8, further comprising a second polymer comprising a repeating unit comprising an acid-labile group, wherein the second polymer is structurally different from the polymer.

10. A method for forming a pattern, the method comprising:
applying a layer of the photoresist composition of claim 8 on a substrate to provide a photoresist composition layer;
pattern-wise exposing the photoresist composition layer to activating radiation to provide an exposed photoresist composition layer; and
developing the exposed photoresist composition layer to provide a photoresist pattern.

11. The photoresist composition of claim 8, wherein in the polymer, the moiety —C(O)-L¹-R¹ comprises an acid labile group.

12. The photoresist composition of claim 8, wherein in the polymer, the base-labile group comprises a fluorinated alkyl ester group, a fluorinated aryl ester group, or a hexafluoroalcohol group.

13. The photoresist composition of claim 8, wherein in the polymer, the second repeating unit is derived from one or more polymerizable compounds that each comprise:
a polymerizable group comprising an ethylenically unsaturated double bond; and
a base-labile group comprising a structure represented by Formula (4), 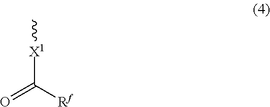
wherein,
X¹ is O, S, or —N(R^{c})—, wherein R^{c} is hydrogen or C₁₋₆ alkyl; and
R^{f} is a substituted or unsubstituted fluoroalkyl group comprising a fluorine atom or a fluoroalkyl group bonded to a carbon atom at an alpha position with respect to the carbonyl group.

14. The photoresist composition of claim 8, wherein in the polymer, the second repeating unit is derived from one or more polymerizable compounds of Formula (5): 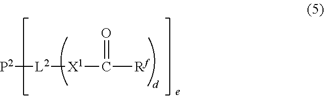
wherein, in Formula (5),
P² is a group comprising an ethylenically unsaturated double bond, wherein P² optionally forms a ring with L²,
L² is a single bond or a linking group;
each X¹ is independently O, S, or —N(R^{c})—, wherein R^{c} is hydrogen or C₁₋₆ alkyl;
each R^{f} independently is a substituted or unsubstituted fluoroalkyl group comprising a fluorine atom or a fluoroalkyl group bonded to a carbon atom at an alpha position with respect to the carbonyl group;
each d is an integer of 1 or greater; and
e is an integer of 1 or greater.

15. The photoresist composition of claim 14, wherein in the polymer, L² comprises an aromatic group substituted with at least one halogen.

16. The method of claim 10, wherein in the polymer, the moiety —C(O)-L¹-R¹ comprises an acid labile group.

17. The method of claim 10, wherein in the polymer, the base-labile group comprises a fluorinated alkyl ester group, a fluorinated aryl ester group, or a hexafluoroalcohol group.

18. The method of claim 10, wherein in the polymer, the second repeating unit is derived from one or more polymerizable compounds that each comprise:
a polymerizable group comprising an ethylenically unsaturated double bond; and
a base-labile group comprising a structure represented by Formula (4), 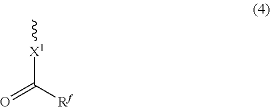
wherein,
X¹ is O, S, or —N(R^{c})—, wherein R^{c} is hydrogen or C₁₋₆ alkyl; and
R^{f} is a substituted or unsubstituted fluoroalkyl group comprising a fluorine atom or a fluoroalkyl group bonded to a carbon atom at an alpha position with respect to the carbonyl group.

19. The method of claim 10, wherein in the polymer, the second repeating unit is derived from one or more polymerizable compounds of Formula (5): 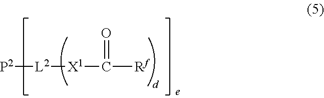
wherein, in Formula (5),
P² is a group comprising an ethylenically unsaturated double bond, wherein P² optionally forms a ring with L²,
L² is a single bond or a linking group;
each X¹ is independently O, S, or —N(R^{c})—, wherein R^{c} is hydrogen or C₁₋₆ alkyl;
each R^{f} independently is a substituted or unsubstituted fluoroalkyl group comprising a fluorine atom or a fluoroalkyl group bonded to a carbon atom at an alpha position with respect to the carbonyl group;
each d is an integer of 1 or greater; and
e is an integer of 1 or greater.

20. The method of claim 19, wherein in the polymer, L² comprises an aromatic group substituted with at least one halogen.
